(19) United States
(12) Patent Application Publication
(10) Pub. No.: US 2025/0120097 A1
(43) Pub. Date: Apr. 10, 2025

(54) MEMORY DEVICE INCLUDING MULTIPLICATE SOURCE LINES AND METHODS OF FORMING THE SAME

(71) Applicant: Taiwan Semiconductor Manufacturing Company Limited, Hsinchu (TW)

(72) Inventors: Sheng-Hung Shih, Hsinchu City (TW); Kuo-Chi Tu, Hsinchu (TW); Wan-Chen Chen, Hsinchu City (TW); Tzu-Yu Chen, Kaohsiung City (TW); Wen-Ting Chu, Kaohsiung City (TW)

(21) Appl. No.: 18/629,037

(22) Filed: Apr. 8, 2024

Related U.S. Application Data
(60) Provisional application No. 63/587,792, filed on Oct. 4, 2023.

(51) Int. Cl. H10B 63/00

(52) U.S. Cl. CPC H10B 63/80; H10B 63/30

(57) ABSTRACT

A memory device includes a two-dimensional array of access transistors located on a semiconductor substrate; metal interconnect structures embedded in dielectric material layers and electrical connected to electrical nodes of the access transistors; and a two-dimensional array of resistive memory structures embedded in the dielectric material layers. The metal interconnect structures include two first source lines located at a first metal line level and laterally extending along a first horizontal direction; a second source line located at a second metal line level and laterally extending along the first horizontal direction; and a vertical connection structure including a plurality of interconnection via structures and at least one line-level metal structure and providing a vertical electrical connection between the two first source lines and the second source line.

### RELATED APPLICATIONS

This application claims the benefit of priority from U.S. Provisional Application Ser. No. 63/587,792 titled “Memory Device Having Reduced Conductive Line Resistance” and filed on Oct. 4, 2023, the entire contents of which are incorporated herein by reference.

### BACKGROUND

Memory devices are susceptible to performance degradation due to high resistance in source lines. Structures and methods for reducing source line resistance in a memory array are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a first configuration of an exemplary structure after formation of an array of access transistors, contact-level via structures, and first-line-level metal interconnect structures according to an embodiment of the present disclosure.

FIG. 1B is a top-down view of the first configuration of the exemplary structure of FIG. 1A. The hinged vertical plane A-A′ is the cut plane of FIG. 1A.

FIG. 1C is a vertical cross-sectional view of the first configuration of the exemplary structure along the vertical plane C-C′ of FIG. 1B.

FIG. 2A is a vertical cross-sectional view of the first configuration of the exemplary structure after formation of additional dielectric material layers and additional metal interconnect structures according to an embodiment of the present disclosure.

FIG. 2B is a top-down view of the first configuration of the exemplary structure of FIG. 2A in which underlying invisible structures are shown in dotted lines. The hinged vertical plane A-A′ is the cut plane of FIG. 2A.

FIG. 2C is a vertical cross-sectional view of the first configuration of the exemplary structure along the vertical plane C-C′ of FIG. 2B.

FIG. 2D is a first redacted version of the top-down view of FIG. 2B in which invisible structural elements underlying word lines are not shown.

FIG. 2E is a second redacted version of the top-down view of FIG. 2B in which invisible structural elements overlying the first-line-level metal interconnect structures are not shown.

FIG. 3A is a vertical cross-sectional view of a second configuration of the exemplary structure according to an embodiment of the present disclosure.

FIG. 3B is a horizontal cross-sectional view of the second configuration of the exemplary structure of FIG. 3A along the horizontal plane B-B′ of FIG. 3A. The hinged vertical plane A-A′ is the cut plane of FIG. 3A.

FIG. 3C is a vertical cross-sectional view of the second configuration of the exemplary structure along the vertical plane C-C′ of FIG. 3B.

FIG. 3D is a horizontal cross-sectional view of the second configuration of the exemplary structure along the horizontal plane D-D′ of FIGS. 3A and 3C.

FIG. 3E is a horizontal cross-sectional view of the second configuration of the exemplary structure along the horizontal plane E-E′ of FIGS. 3A and 3C.

FIG. 4A is a vertical cross-sectional view of a third configuration of the exemplary structure according to an embodiment of the present disclosure.

FIG. 4B is a horizontal cross-sectional view of the third configuration of the exemplary structure of FIG. 4A along the horizontal plane B-B′ of FIG. 4A. The hinged vertical plane A-A′ is the cut plane of FIG. 4A.

FIG. 4C is a horizontal cross-sectional view of the third configuration of the exemplary structure along the horizontal plane C-C′ of FIG. 4A.

FIG. 4D is a horizontal cross-sectional view of an alternative embodiment of the third configuration of the exemplary structure within a horizontal plane that corresponds to the horizontal plane B-B′ of FIG. 4A.

FIG. 5A is a vertical cross-sectional view of a fourth configuration of the exemplary structure according to an embodiment of the present disclosure.

FIG. 5B is a horizontal cross-sectional view of the fourth configuration of the exemplary structure of FIG. 5A along the horizontal plane B-B′ of FIG. 5A. The hinged vertical plane A-A′ is the cut plane of FIG. 5A.

FIG. 5C is a horizontal cross-sectional view of the fourth configuration of the exemplary structure along the horizontal plane C-C′ of FIG. 5A.

FIG. 6 is a flowchart illustrating steps for forming a memory device according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. Drawings are not drawn to scale. Elements with the same reference numerals refer to the same element, and are presumed to have the same material composition and the same thickness range unless expressly indicated otherwise. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Ordinals such as “first,” “second,” “third,” etc. are generally not a part of a noun that refers to an element, but are merely adjectives. As such, same elements may be referred to with different ordinals across the specification and the claims. Further, whenever multiple elements and/or similar elements are present, such multiple elements and/or similar elements may be numbered in any order. Thus, the possibility of numbering elements with different ordinals are expressly contemplated for each case in which a plurality of elements is present. Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Performance of resistive random access memory (RRAM) devices may be enhanced by reducing resistance of metal interconnect structures that provide electrical wiring to the RRAM devices. The voltage drop on the source side of an access transistor may also result in resistive heating of the access transistor, and may lead to device degradation and reliability issues during operation of the RRAM devices. Thus, low resistance of the source line may stabilize the threshold voltage for the access transistors by providing sufficient electrical current flow through the access transistor while minimizing the voltage drop on the source side during operation of the RRAM devices. The size and the power consumption level of a RRAM array may also affect the resistance requirement of the metal wiring in the RRAM array. For example, a large RRAM array requires a higher current handling capability. Thus, it is desirable to reduce the resistance of metal wiring in RRAM devices, and particularly for in a RRAM array including a large number of RRAM cells. A drift in the source voltage in a RRAM device has a more detrimental effect in the device performance than voltage drifts in word lines or bit lines, and thus, it is desired to reduce source resistance to achieve reliable operation of a RRAM array.

The desire to lower the source resistance in a RRAM array stems from the intrinsic operational characteristics of these memory devices, as well as their susceptibility to performance degradation due to voltage drifts. Generally, RRAM devices store data by changing the resistance of a dielectric material between two electrodes through the application of a voltage. This change in resistance represents binary data states (0 and 1). The operation of RRAM involves several key voltages, including those applied to the word lines (WLs), bit lines (BLs), and the source line. These voltages control the writing, reading, and erasing of data in the RRAM array.

Voltage drifts refer to unwanted variations in the applied voltages, which may be particularly problematic for the precise control needed in RRAM operation. A drift in the source line (SL) voltage is more detrimental than drifts in WL or BL voltages for several reasons.

A first reason is threshold switching precision that is required for operation of RRAM devices. RRAM devices operate by inducing a switch in the material's resistance state when a certain threshold voltage is exceeded. In instances in which the source voltage drifts, the exact threshold point for switching may become unpredictable, leading to unreliable data storage and retrieval. Lower source resistance contributes to a more uniform application of the voltage across the array. High source resistance may lead to voltage drops, meaning not all cells in the array receive the same voltage during operations. This can cause non-uniformity in switching behaviors, adversely affecting device reliability and data integrity.

A second reason is energy efficiency. Higher source resistance requires higher voltages to achieve the same electric field across the RRAM material, leading to increased power consumption. Reducing source resistance may improve the energy efficiency of the device, which is beneficial for battery-powered and low-power applications.

A third reason is reliability of RRAM devices. Voltage instability, partly due to high source resistance, may lead to more frequent and erratic switching, stressing the material and potentially reducing the device's lifetime. Embodiments of the present disclosure may be used to reduce the source resistance within a RRAM array. The various aspects of the present disclosure are now described with reference to accompanying drawings.

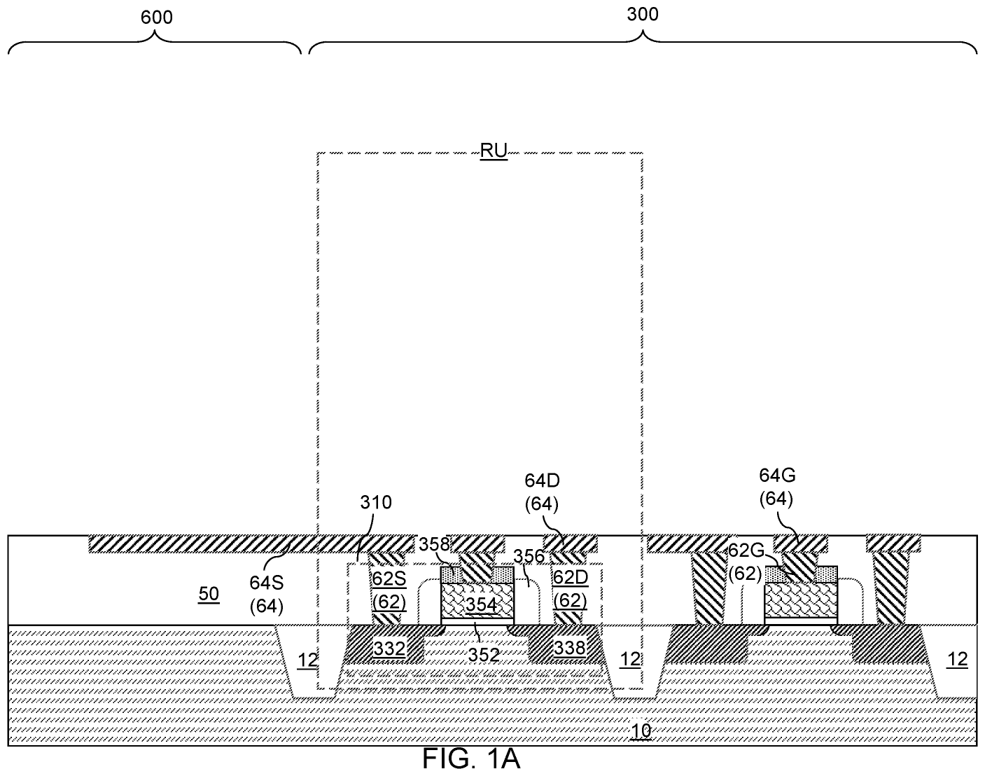

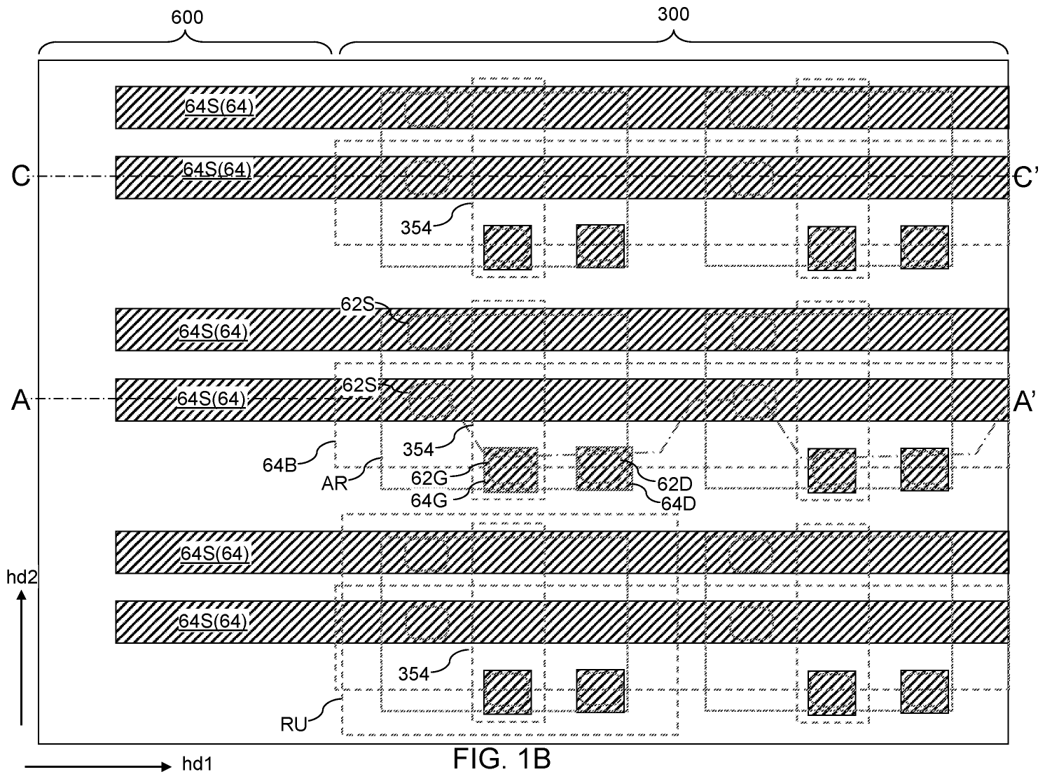

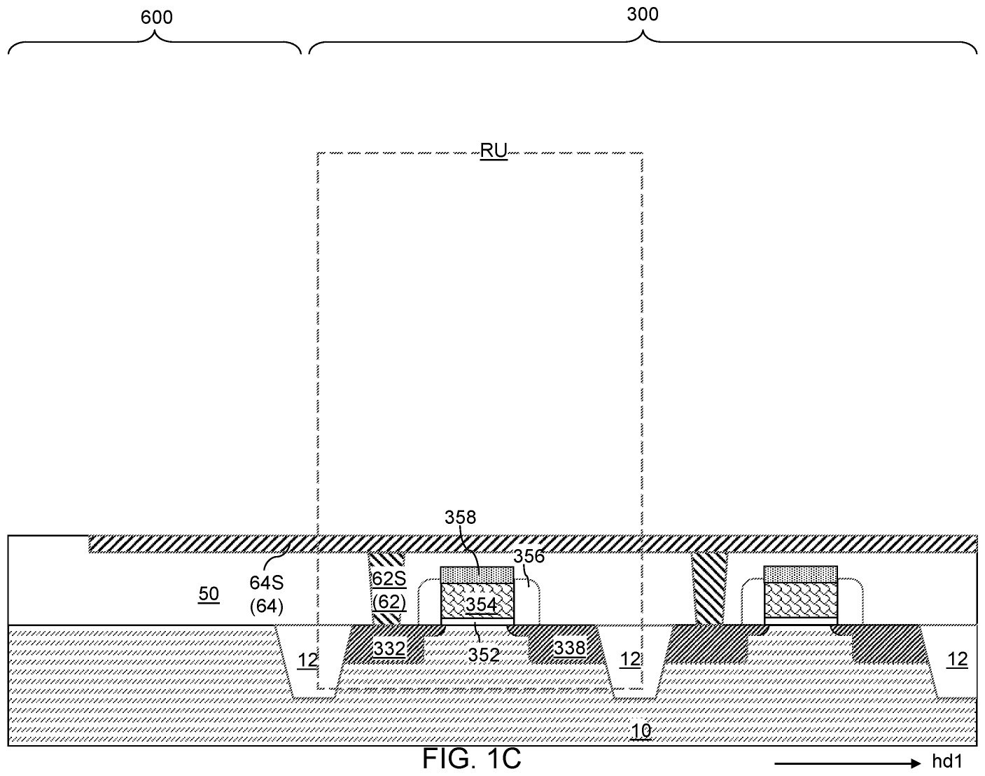

Referring to FIGS. 1A-1C, a first configuration of an exemplary structure is illustrated. The first configuration of the exemplary structure comprises a semiconductor substrate 10, and an array of access transistors 310 that is formed on the semiconductor substrate 10 in a memory array region 300. The semiconductor substrate 10 may comprise a bulk semiconductor substrate or a semiconductor-on-insulator (SOI) substrate. The semiconductor substrate 10 may be a commercially available single crystalline silicon wafer.

The memory array region 300 is a region in which a resistive memory array is subsequently formed. According to an aspect of the present disclosure, a vertical connection region 600 is provided adjacent to an edge of the memory array region 300. Vertical connection structures that provide vertically-extending electrically conductive paths are subsequently formed in the vertical connection region 600.

Shallow trenches may be formed in an upper portion of the semiconductor substrate 10, and may be filled with a dielectric material to form shallow trench isolation structures 12. In one embodiment, the shallow trench isolation structures 12 may have a pattern of a grid containing a rectangular array of M×N openings therethrough. Each opening in the shallow trench isolation structures 12 defines an active region AR in which a source region 332, a drain region 338, and a channel region of a respective access transistor 310 is formed. The integer M may be in a range from 2 to 2¹⁶, although a greater number may also be used. The integer N may be in a range from 2 to 2¹⁶, although a greater number may also be used. Each active region AR may be located entirely within the area of a repetition unit RU in a plan view, such as a top-down view of FIG. 1B.

Generally, a two-dimensional array of resistive memory devices may be formed in the memory array region 300. Each resistive memory device may constitute a repetition unit RU of the two-dimensional array. Each resistive memory device may comprise an access transistor 310 that is formed on a top surface of the semiconductor substrate 10, a resistive memory structure to be subsequently formed, and metal interconnect structures that are used to electrically connect a drain region of the access transistor 310 to an electrode of the resistive memory structure, to electrically bias various nodes of the access transistor 310 and the resistive memory structure.

For example, the two-dimensional array of resistive memory devices may comprise an M×N rectangular array of resistive memory devices including M rows and N columns. Each column of resistive memory derives may be arranged along a first horizontal direction hd1, and neighboring columns of resistive memory devices may be laterally spaced apart along a second horizontal direction hd2. Each row of resistive memory derives may be arranged along the second horizontal direction hd2, and neighboring rows of resistive memory devices may be laterally spaced apart along the first horizontal direction hd1. In one embodiment, each column of resistive memory devices may contain M resistive memory devices arranged along the first horizontal direction hd1. In one embodiment, each row of resistive memory device may contain N resistive memory devices arranged along the second horizontal direction hd2.

Specifically, a two-dimensional array of access transistors 310 may be formed on the semiconductor substrate 10. Each access transistor 310 comprises a source region 332, a drain region 338, a gate stack including a gate dielectric 352, a gate electrode 354, and a gate cap dielectric 358, and a gate spacer 356. The source region 332 may comprise a combination of a source extension region and a deep source region. The drain region 338 may comprise a combination of a drain extension region and a deep drain region. Each column of access transistors 310 may be arranged along the first horizontal direction hd1, and each row of access transistors 310 may be arranged along the second horizontal direction hd2.

Dielectric material layers may be formed over the two-dimensional array of access transistors 310. The dielectric material layers are herein referred to as lower-level dielectric material layers 50. Lower-level metal interconnect structures (62, 64) may be formed in the lower-level dielectric material layers 50. The lower-level metal interconnect structures (62, 64) may comprise metal via structures 62 and metal line structures 64. The level at which metal via structures contacting the source regions 332 or drain regions 338 are formed is herein referred to as a contact level. The metal via structures 62 that are formed at this processing step may comprise contact-level metal via structures (62S, 62D, 62G), i.e., metal via structures that are formed at the contact level. The contact-level metal via structures (62S, 62D, 62G) include source contact via structures 62S, drain contact via structures 62D, and gate contact via structures 62G.

The level at which metal lines that contact top surfaces of the contact-level metal via structures (62S, 62D, 62G) are formed is herein referred to as a first-metal-line level, i.e., a first level at which metal lines are formed as counted in the order of proximity to the semiconductor substrate 10. The metal line structures 64 that are formed at this processing step may comprise first-line-level metal lines (64S, 64D, 64G), i.e., metal line structures that are formed at the first-metal-line level, or an M1 level, which is a line level that is most proximal to the semiconductor substrate 10. The first-line-level metal lines (64S, 64D, 64G) include first source lines 64S, first-line-level drain-connection metal lines 64D, and first-line-level gate-connection metal lines 64G. The top surfaces of the first-line-level metal lines (64S, 64D, 64G) may be formed within a same horizontal plane.

Each first source line 64S contacts a respective column of M source contact via structures 62S that are arranged along the first horizontal direction hd1, and is electrically connected to M source regions 332 in a respective column of M access transistors 310 that are arranged along the first horizontal direction hd1. Each first-line-level drain-connection metal line 64D may have a configuration of a metal pad, may have a lesser area than the area of a respective underlying drain region 638, and may be electrically connected to the drain region 338 of a respective underlying access transistor 310 through a respective drain contact via structure 62D. Each first-line-level gate-connection metal lines 64G may have a configuration of a metal pad, may have a lesser area than the area of a respective underlying gate electrode, and may be electrically connected to the drain region 338 of a respective underlying access transistor 310 through a respective drain contact via structure 62D.

The metal line structures 64 within the lower-level metal interconnect structures (62, 64) are generally formed within the memory array region 300 except for the first source lines 64S, which laterally extend through the memory array region 300 and into the vertical connection region 600.

In one embodiment, all metal lines in the first metal line level may laterally extend along the first horizontal direction hd1 and may have a uniform lateral dimension, i.e., a uniform width, along the second horizontal direction hd2. Neighboring pairs of metal lines in the first metal line level may be laterally spaced from each other by a uniform lateral spacing. The sum of the uniform width of each first-line-level metal line (64S, 64D, 64G) and the uniform lateral spacing at the first metal line level defines a line pattern pitch of the first-line-level metal line (64S, 64D, 64G) along the second horizontal direction hd2.

The first source lines 64S, the first-line-level drain-connection metal lines 64D, and the first-line-level gate-connection metal lines 64G may be located at the first metal line level. The first metal line level is vertically spaced from a top surface of the semiconductor substrate 10 by a first vertical spacing. The first source lines 64S laterally extend along the first horizontal direction hd1, and are laterally spaced from each other along a second horizontal direction hd2. Each source region 332 within a column of access transistors 310 is electrically connected to each of the two first source lines 64S that overlies the column of access transistors 310.

According to an aspect of the present disclosure, each repetition unit RU may have a rectangular shape in in a plan view (such as a top-down view of FIG. 1B), and the width of the rectangular shape of each repletion unit in the plan view along the second horizontal direction hd2 may be qual to three times the line pattern pitch of the first-line-level metal lines (64S, 64D, 64G) along the second horizontal direction hd2. In other words, three metal lines of the same width along the second horizontal direction hd2 may fit into the rectangular area of a repetition unit RU.

In one embodiment, two first source lines 64S, a column of M first-line-level drain-connection metal lines 64D, and a column of M first-line-level gate-connection metal lines 64G may be formed within each area of a column of M repletion units RU that are arranged along the first horizontal direction hd1. Each of the two first source lines 64S may continuously extend over each of M access transistors 310 within the area of the column of M repletion units RU.

Two first source lines 64S and two columns of source contact via structures 62S may be arranged along the first horizontal direction hd1 within the area of a column of access transistors 310. Each source contact via structure 62S contacts a bottom surface of a respective one of the two first source lines 64S, and contacts a top surface of a source region 332 of a respective access transistor 310 within the column of access transistors 310. Each source region 332 within the column of access transistors 310 is contacted by a respective first source contact via structure 62S that contacts a bottom surface of one of the two first source lines 64S, and by a respective second source contact via structure 62S that contacts a bottom surface of another of the two first source lines 64S.

The column of M first-line-level drain-connection metal lines 64D may be located between a pair of first source lines 64S overlying a neighboring pair of columns of access transistors 310. Each first-line-level drain-connection metal line 64D may have a configuration of a metal pad, and may have a lateral extent along the first horizontal direction hd1 that is less than one half, and preferably less than one third, of the length of the rectangular shape of the repetition unit RU along the first horizontal direction hd1. The column of M first-line-level drain-connection metal lines 64D may be electrically connected to a column of drain regions 338 through a column of drain contact via structures 62D.

The column of M first-line-level gate-connection metal lines 64G may be located between a pair of first source lines 64S overlying a neighboring pair of columns of access transistors 310. Each first-line-level gate-connection metal line 64G may have a configuration of a metal pad, and may have a lateral extent along the first horizontal direction hd1 that is less than one half, and preferably less than one third, of the length of the rectangular shape of the repetition unit RU along the first horizontal direction hd1. The column of M first-line-level gate-connection metal lines 64G may be electrically connected to a column of gate electrodes 354 through a column of gate contact via structures 62G.

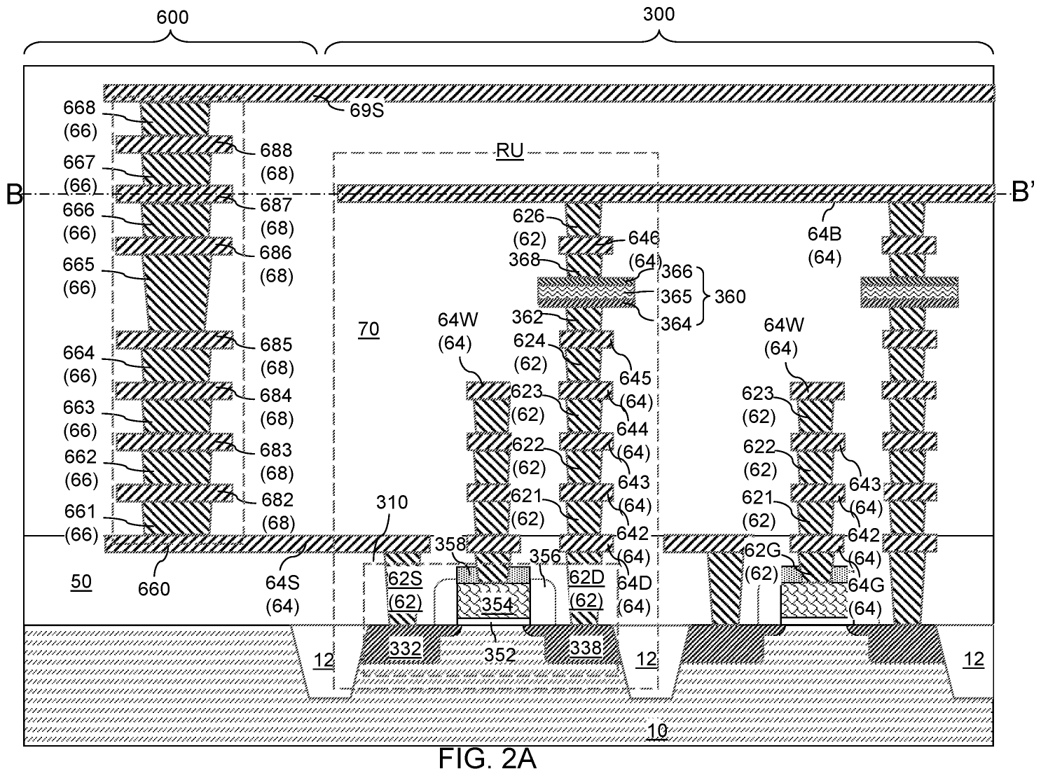

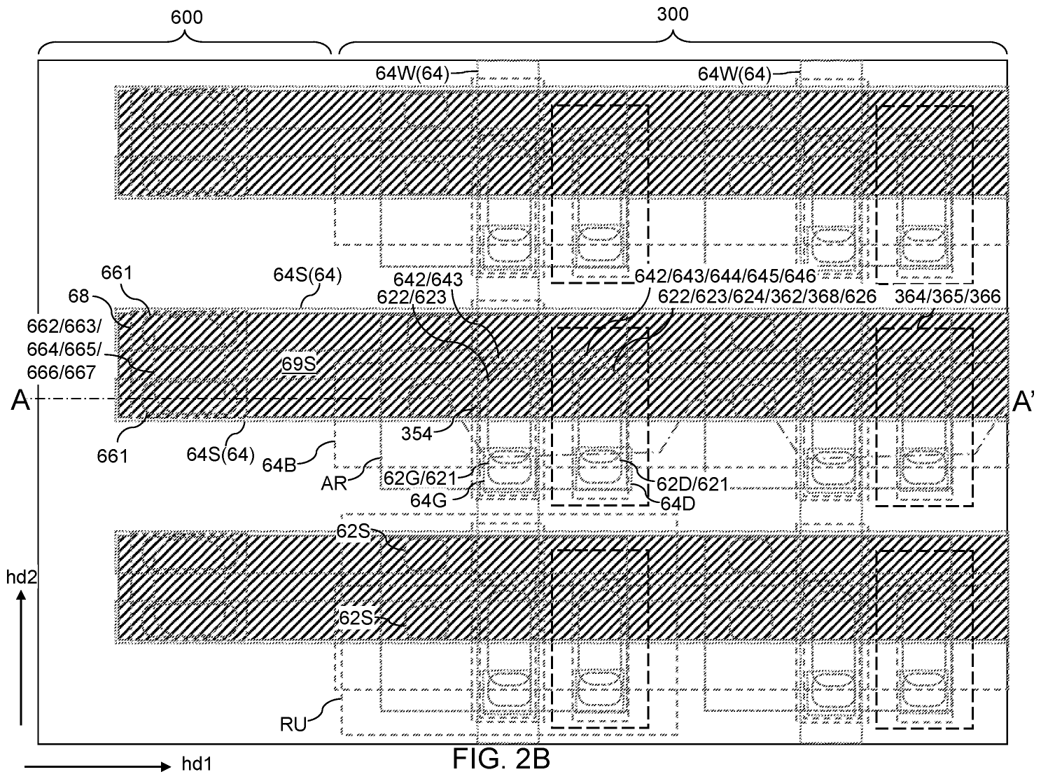

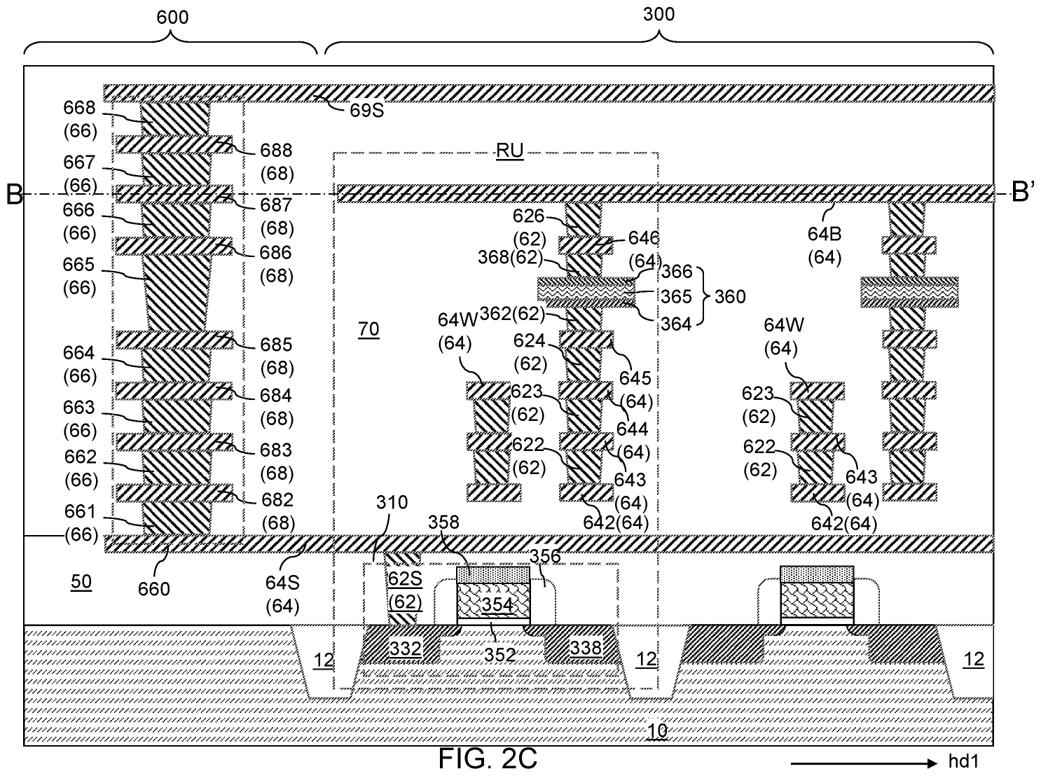

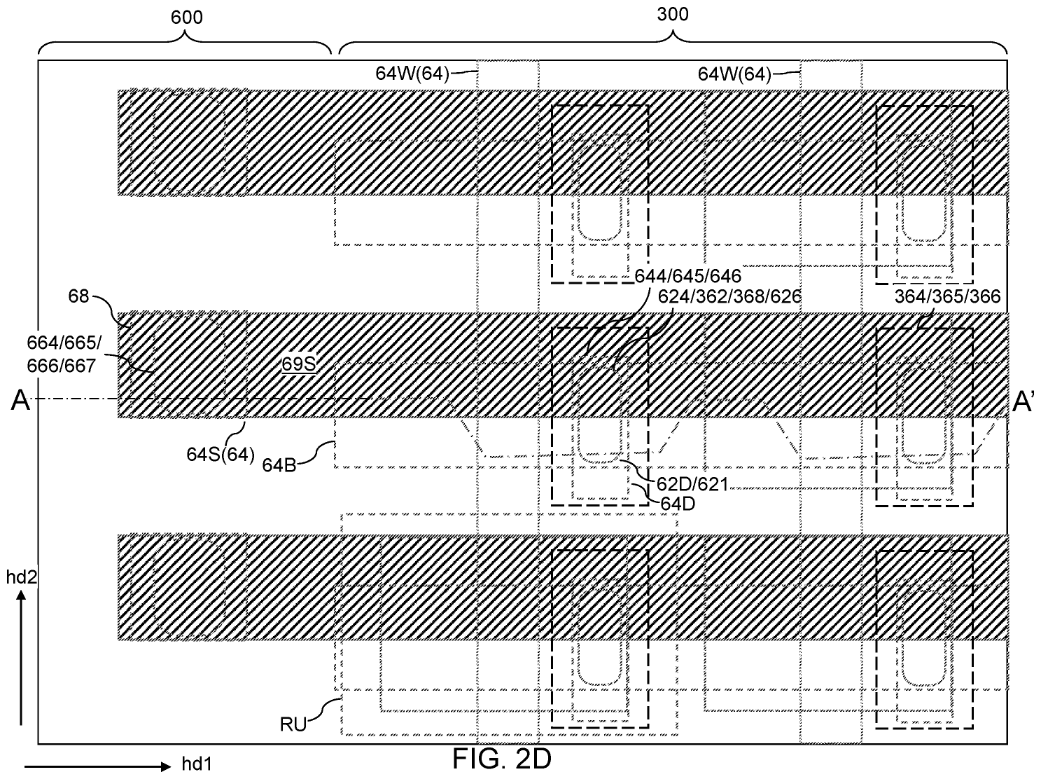

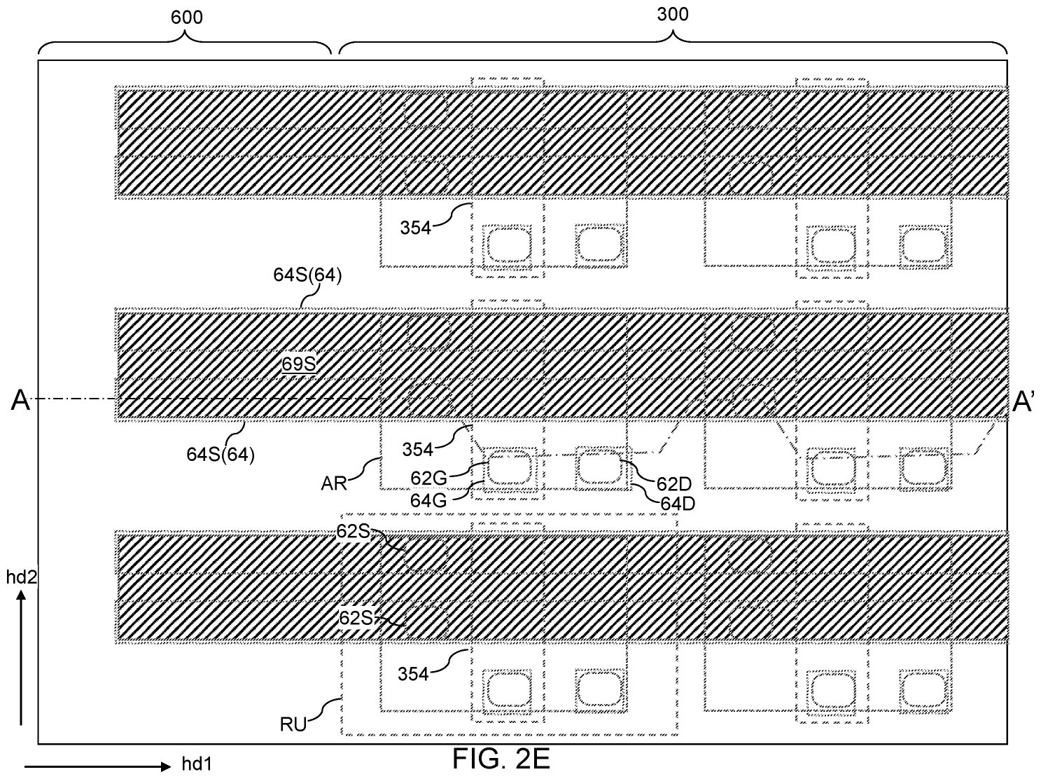

Referring to FIGS. 2A-2E, additional dielectric material layers and additional metal interconnect structures and may be formed over the first-line-level metal lines (64S, 64D, 64G). The additional dielectric material layers are herein referred to as upper-level dielectric material layers 70. The additional metal interconnect structures are herein referred to as upper-level metal interconnect structures (62, 64, 66, 68). A two-dimensional array of resistive memory structures 360 may be formed within the upper-level dielectric material layers 70. The two-dimensional array of resistive memory structures 360 may be formed entirely within the memory array region 300 in a plan view.

The upper-level metal interconnect structures (62, 64, 66, 68) comprise metal via structures 62 that are formed at metal via levels within the memory array region 300, metal line structures 64 that are formed at metal line levels within the memory array region 300, metal via structures 66 that are formed in the vertical connection region 600 at the metal via levels in the vertical connection region 600, and at least one line-level metal structure 68 that are formed in the vertical connection region 600 at the metal line levels. The metal line structures 64 within the upper-level metal interconnect structures (62, 64, 66, 68) are generally formed within the memory array region 300 except for second source lines 65S, which laterally extend through the memory array region 300 and into the vertical connection region 600. Generally, the metal interconnect structures (62, 64, 66, 68) are embedded in dielectric material layers (50, 70), and are electrical connected to electrical nodes of the access transistors 310.

The metal line structures 64 may comprise second-line-level line structures 642 that are formed in a second-metal-line level, third-line-level line structures 643 that are formed in a third-metal-line level, fourth-line-level line structures 644 that are formed in a fourth-metal-line level, fifth-line-level line structures 645 that are formed in a fifth-metal-line level, sixth-line-level line structures 646 that are formed in a sixth-metal-line level, etc. Each n-th-metal-line level, or an Mn level, is a line level that is the n-th in the order of proximity to the semiconductor substrate 10 among all the metal line levels. The integer n may range from 2 to 20, although a greater number may also be used for the value of the integer n.

In one embodiment, a first subset of the metal line structures 64 that is formed at odd-numbered metal line levels may laterally extend along a horizontal direction (such as the first horizontal direction hd1), and a second subset of the metal line structures 64 that is formed at even-numbered metal line levels may laterally extend along another horizontal direction (such as the second horizontal direction hd2 that is perpendicular to the first horizontal direction hd1). For example, the first source lines 64S and the first-line-level drain-connection metal lines 64D, the third-line-level line structures 643, the fifth-line-level line structures 645, the seventh-line-level line structures 647, etc. can laterally extend along the first horizontal direction hd1, and the second-line-level line structures 642, the fourth-line-level line structures 644, the sixth-line-level line structures 648, etc. can laterally extend along the second horizontal direction hd2.

The metal via structures 62 may comprise first-via-level connection via structures 621 that are formed in a first-metal-via level, second-via-level connection via structures 622 that are formed in a second-metal-via level, third-via-level connection via structures 623 that are formed in a third-metal-via level, fourth-via-level connection via structures 624 that are formed in a fourth-metal-via level, sixth-via-level connection via structures 626 that are formed in a sixth-metal-via level, etc. Each n-th-metal-via level, or an Vn level, is a via level that is the n-th in the order of proximity to the semiconductor substrate 10 among all the metal via levels excluding the contact via level. The integer n may range from 2 to 19, although a greater number may also be used for the value of the integer n.

A subset of the metal line structures 64 within the upper-level metal interconnect structures (62, 64, 66, 68) comprise word lines 64W, which may laterally extend continuously along the second horizontal direction hd2 across areas of a respective row of access transistors 310 in a plan view (such as the views in FIGS. 2B and 2D). In the illustrated example, the word lines 64W are formed at the fourth metal line level. In a layout in which metal lines at odd-numbered metal line levels laterally extend along the first horizontal direction hd1, and metal lines at even-numbered metal line levels laterally extend along the second horizontal direction hd2, the word lines 64W may be formed at any of the even-numbered metal line levels. A subset of the metal via structures 62 and the metal line structures 64 provide electrical connection to and from the gate electrodes 354 and the word lines 64W.

A subset of the metal line structures 64 within the upper-level metal interconnect structures (62, 64, 66, 68) comprise bit lines 64B, which may laterally extend continuously along the first horizontal direction hd1 across areas of a respective column of access transistors 310 in the plan view (such as the views in FIGS. 2B and 2E). In the illustrated example, the bit lines 64B are formed at the seventh metal line level. In a layout in which metal lines at odd-numbered metal line levels laterally extend along the first horizontal direction hd1, and metal lines at even-numbered metal line levels laterally extend along the second horizontal direction hd2, the bit lines 64B may be formed at any of the odd-numbered metal line levels other than the first metal line level. A subset of the metal via structures 62 and the metal line structures 64 provide electrical connection to and from the second electrodes 366 of the resistive memory structures 360 and the bit lines 64B.

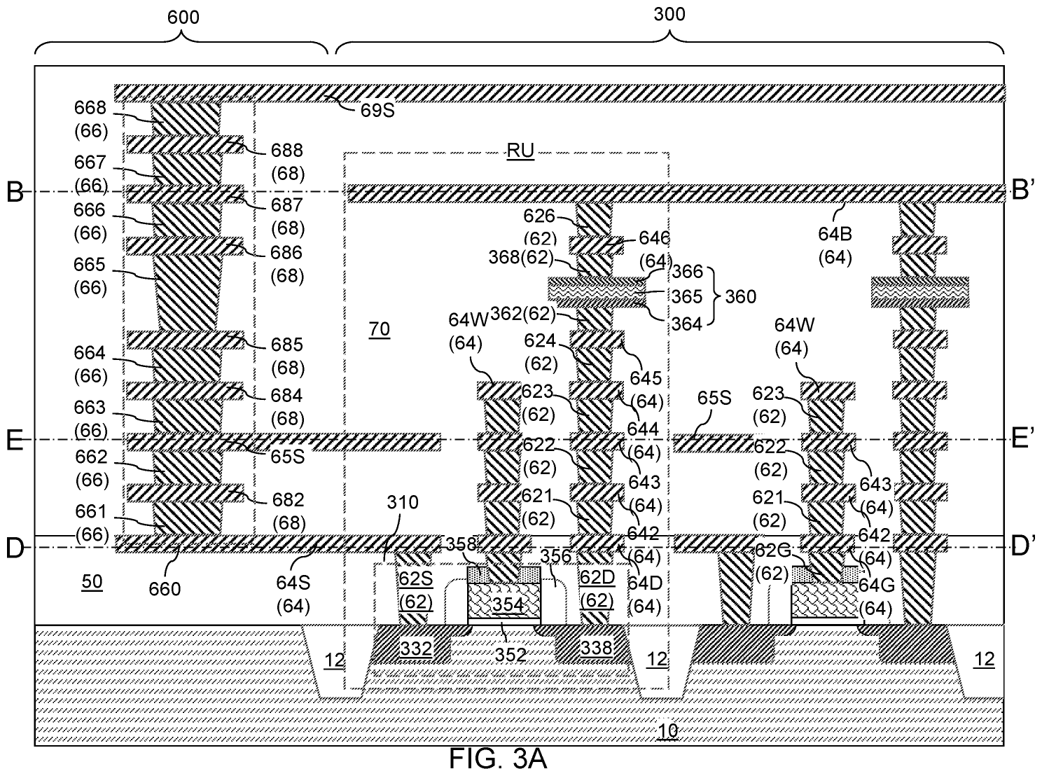

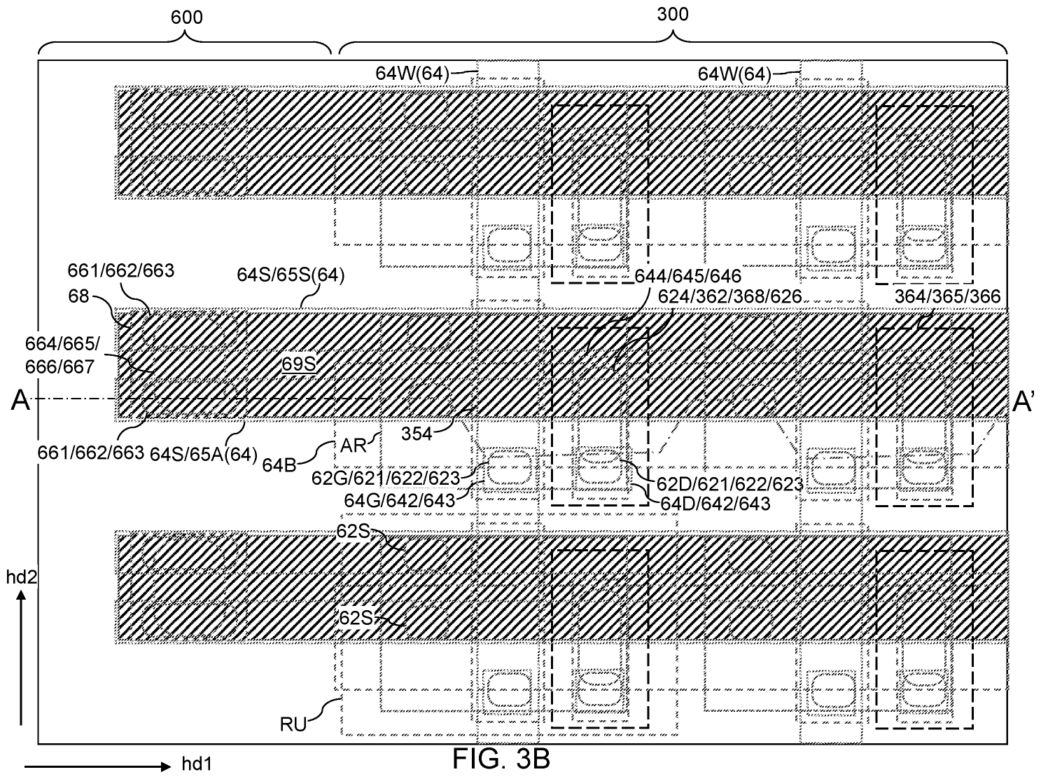

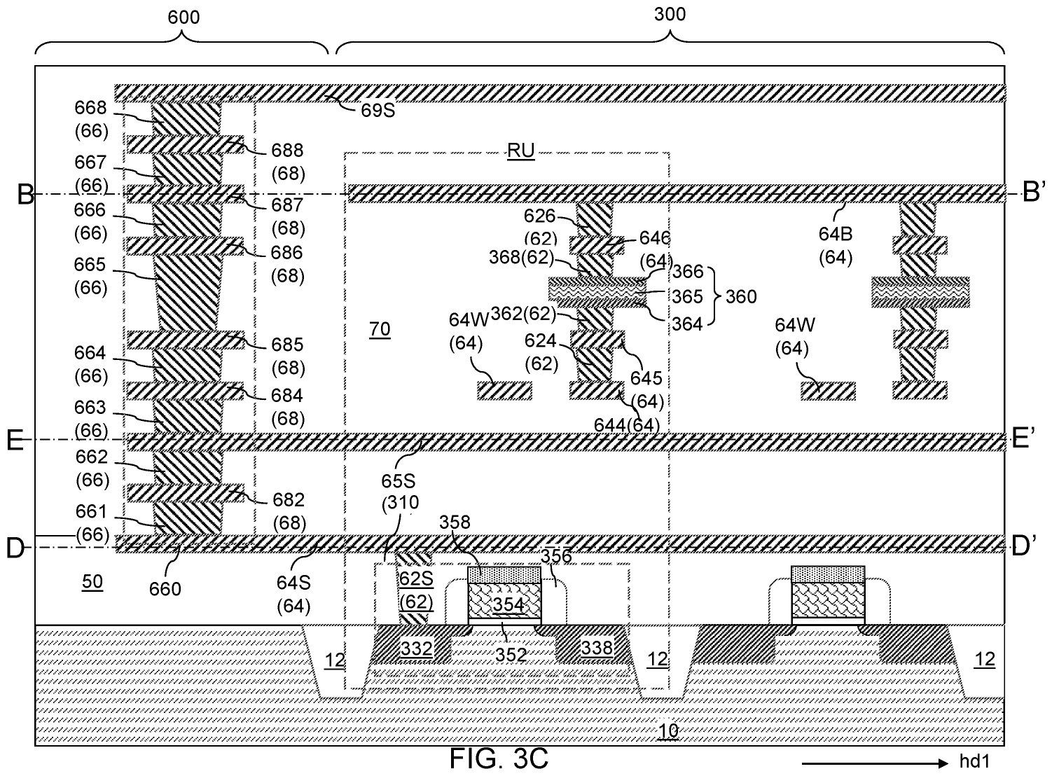

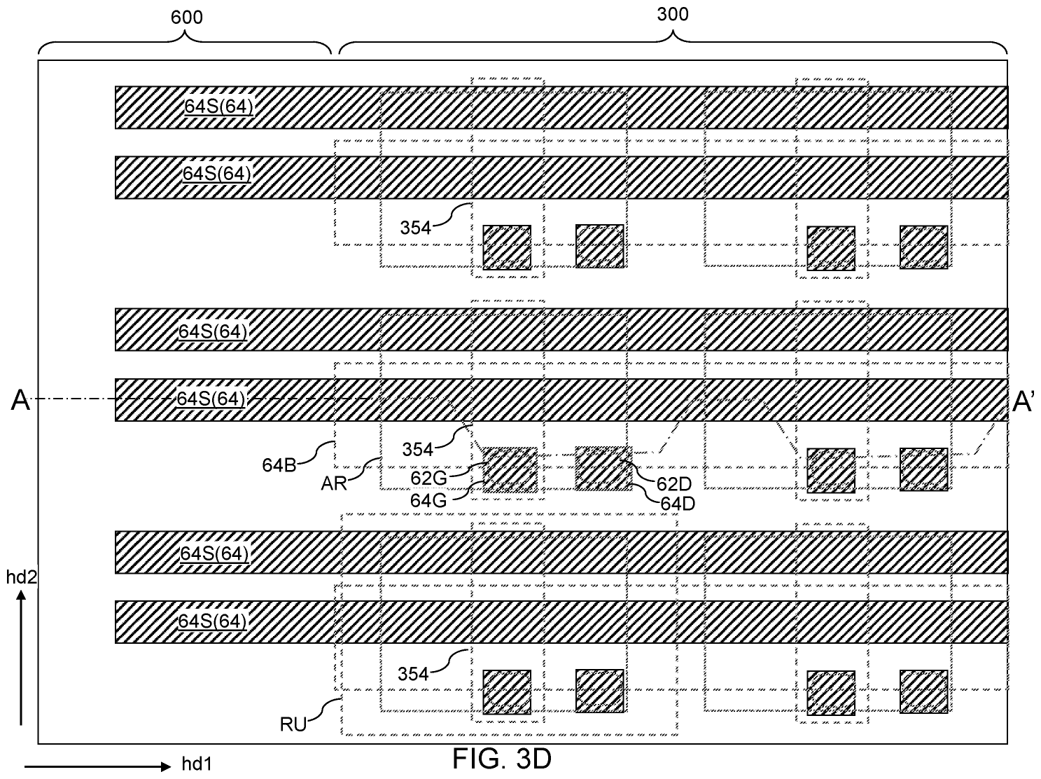

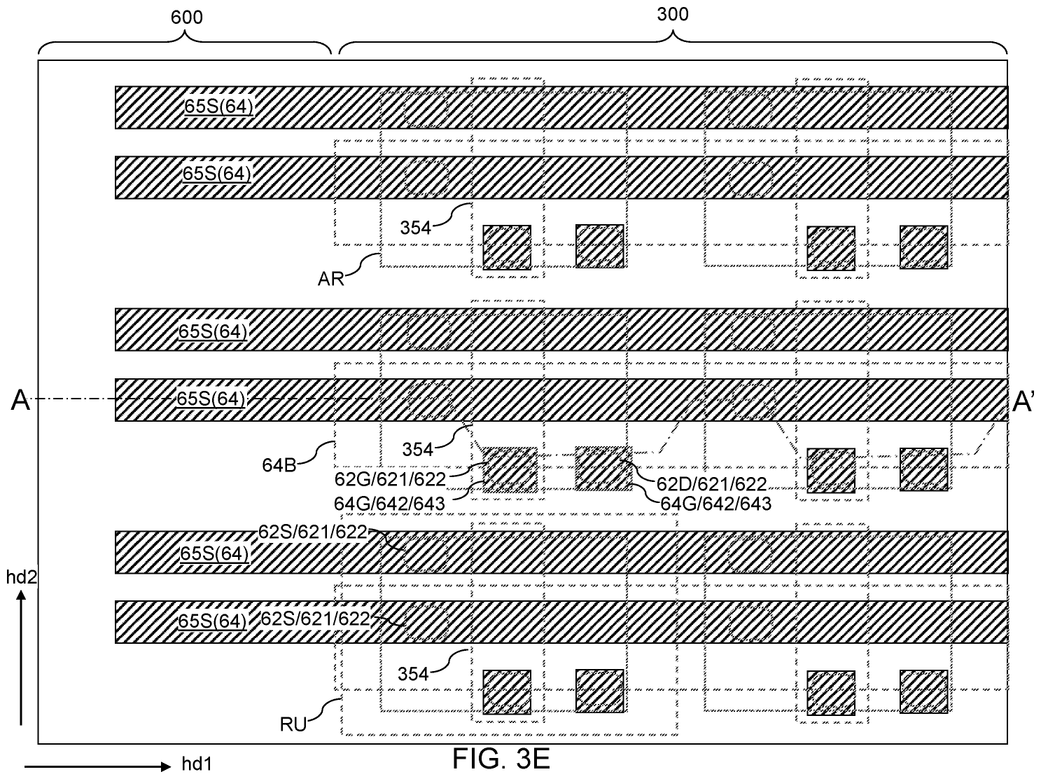

A resistive memory device is formed within the volume of each repetition unit RU. Each resistive memory device may comprise an access transistor 310, a resistive memory structure 360, and a subset of the metal interconnect structures (62, 64) that are located within the volume of a respective repetition unit RU. Each resistive memory structure 360 comprises a first electrode 364 (which may be a bottom electrode), a resistive memory element 365 comprising a material that provides at least two different resistive states, and a second electrode 366 (which may be a top electrode). The first electrode 364 may comprise a first inert metallic material such as TiN, TaN, WN, and/or MoN. The second electrode 366 may comprise a second inert metallic material such as TiN, TaN, WN, and/or MoN. The metal via structures 62 may comprise bottom-electrode-contact via structures 362 contacting bottom surfaces of the first electrodes 364 (which are bottom electrodes), and top-electrode-contact via structures 368 contacting top surfaces of the second electrodes 366 (which are top electrodes). Generally, the array of resistive memory structures 360 may be formed within a metal via level (e.g., a fifth metal via level as illustrated in FIGS. 3A and 3C).

The material of each resistive memory element 365 that provides at least two different resistive states is herein referred to as a resistive memory material. Generally, the resistive memory material may be any type of resistive memory material known in the art. In one embodiment, the resistive memory material may comprise a filament-forming metal oxide material which provides a higher conductivity upon formation of conductive filaments therein (such as hafnium oxide, titanium oxide, niobium pentoxide, germanium telluride, silver sulfate, zinc oxide, vanadium oxide, tantalum oxide, zirconium oxide, etc.). In one embodiment, the resistive memory material may comprise a phase change memory material containing a chalcogenide glass (such as an alloy of germanium, antimony, and tellurium, and optionally additional additives). In one embodiment, the resistive memory material may comprise a conductive bridge-forming material in which conductive bridges may be formed or ruptured (such as silver, copper, silver sulfide, mixed ionic-electronic conductor materials (e.g., yttria-stabilized zirconia), etc.). In one embodiment, the resistive memory material may comprise an organic polymer material that may provide at least two different resistive states. In one embodiment, the resistive memory material may comprise a perovskite-based material that may provide at least two different resistive states. In one embodiment, the resistive memory material may comprise a two-dimensional material such as molybdenum disulfide (MoS₂) that may provide at least two different resistive states. In one embodiment, the resistive memory material may comprise an organic-inorganic hybrid resistive memory material that may provide at least two different resistive states. In one embodiment, the resistive memory material may comprise a rare earth oxide resistive memory material that may provide at least two different resistive states.

In embodiments in which the repetition unit RU is repeated in a pattern of an M x N rectangular array as discussed above, an M×N array of access transistors 310, an M×N array of resistive memory structures 360, and an M×N array of assemblies of metal interconnect structures (62, 64) may be provided. Each assembly of metal interconnect structures (62, 64) may be configured to provide electrical connections to a respective access transistor 310 and to a respective resistive memory structure 360.

According to an aspect of the present disclosure, second source lines 69S may be formed at a metal line level that overlies the first metal line level. Generally, the metal line level of the second source lines 69S is herein referred to as a second metal line level, which is a different from the first metal line level in which the first source lines 64S are formed. As discussed above, the first metal line level may be the first-metal-line level. Generally, the second metal line level may be any of the odd-numbered metal line levels as counted upward from the top surface of the semiconductor substrate 10. In the illustrated example of FIGS. 2A-2E, the second metal line level may be the ninth level. The second metal line level is vertically spaced from the top surface of the semiconductor substrate 10 by a second vertical spacing that is different from the first vertical spacing between the first metal line level and the top surface of the semiconductor substrate 10.

The second source lines 69S laterally extend along the first horizontal direction hd1, and may have a uniform width along the second horizontal direction hd2. In one embodiment, the second source lines 69S may be formed in a “fat line level,” which has a greater line pitch along the second horizontal direction hd2 than the line pitch at the first-metal-line level, i.e., the M1 level. In one embodiment, the line pitch of the second source lines 69S along the second horizontal direction hd2 may be the same as the width of the rectangular shape of the repetition unit RU in the plan view along the second horizontal direction hd2. Thus, the pattern of the second source lines 69S may be repeated along the second horizontal direction hd2 with the same periodicity as the width of the rectangular shape of the repetition unit RU in the plan view along the second horizontal direction hd2. In one embodiment, the width of each second source line 69S along the second horizontal direction hd2 may be the same as, or may be about, up to three times the width of each first source line 64S.

According to an aspect of the present disclosure, vertical connection structure 660 are formed in the upper-level dielectric material layers 70 within the vertical connection region 600, which is located outside the memory array region 300. Each vertical connection structure 660 comprises a stack of a plurality of interconnection via structures 66 and at least one line-level metal structure 68, and provides a vertical electrical connection between a respective set of two first source lines 64S and a second source line 69S. In one embodiment, each vertical connection structure 660 may comprise a vertically alternating sequence of a plurality of interconnection via structures 66 and a plurality of line-level metal structures 68.

The interconnection via structures 66 may comprise first-via-level connection via structures 661 that are formed in a first-metal-via level, second-via-level connection via structures 662 that are formed in a second-metal-via level, third-via-level connection via structures 663 that are formed in a third-metal-via level, fourth-via-level connection via structures 664 that are formed in a fourth-metal-via level, fifth-via-level connection via structures 665 that are formed in a fifth-metal-via level, sixth-via-level connection via structures 666 that are formed in a sixth-metal-via level, seventh-via-level connection via structures 667 that are formed in a seventh-metal-via level, eighth-via-level connection via structures 668 that are formed in an eighth-metal-via level, etc. Each n-th-metal-via level, or an Vn level, is a via level that is the n-th in the order of proximity to the semiconductor substrate 10 among all the interconnection via levels excluding the contact via level. The integer n may range from 2 to 19, although a greater number may also be used for the value of the integer n.

The line-level metal structures 68 may comprise second-line-level metal structures 682 that are formed in a second-metal-line level, third-line-level metal structures 65S that are formed in a third-metal-line level, fourth-line-level metal structures 684 that are formed in a fourth-metal-line level, fifth-line-level metal structures 685 that are formed in a fifth-metal-line level, sixth-line-level metal structures 686 that are formed in a sixth-metal-line level, seventh-line-level metal structures 687 that are formed in a seventh-metal-line level, eighth-line-level metal structures 688 that are formed in an eighth-metal-line level, etc. Each n-th-metal-line level, or an Mn level, is a line level that is the n-th in the order of proximity to the semiconductor substrate 10 among all the metal line levels. The integer n may range from 2 to 20, although a greater number may also be used for the value of the integer n.

Generally, for each column of resistive memory structures 360 that is electrically connected to a column of access transistors 310, each resistive memory structure 360 within the column of resistive memory structures 360 is electrically connected to a drain region of a respective access transistor 310 within the column of access transistors 310. For each combination of a column of resistive memory structures 360 and a column of access transistors 310, two source lines 64S are provided at a first metal line level that is vertically spaced from the top surface of the semiconductor substrate 10 by a first vertical spacing. For each combination of a column of resistive memory structures 360 and a column of access transistors 310, a second source line 69S may be provided, which is located at a second metal line level that is vertically spaced from the top surface of the semiconductor substrate 10 by a second vertical spacing that is different from the first vertical spacing, and laterally extends along the first horizontal direction hd1, and is electrically connected to each of the two first source lines 64S.

In one embodiment, each column of access transistors 310 is formed within a memory array region 300, and each the vertical connection structure 660 is formed within a vertical connection region 600 that is laterally offset from the memory array region 300 in a plan view. For each column of access transistors 310, two first source lines 64S, a column of first source contact via structures 62S, and a column of second source contact via structures 62S may be provided. One of the two first source lines 64S is formed on the column of first source contact via structures 62S, and another of the two first source lines 64S is formed on the column of second source contact via structures 62S. Each source region 332 within the column of access transistors 310 is contacted by a respective one of the first source contact via structures 62S and by a respective one of the second source contact via structures 62S.

In one embodiment, each vertical connection structure 660 continuously extends from top surfaces of a respective set of two first source lines 64S to a bottom surface of a respective second source line 69S. In one embodiment, the two first source lines 64S laterally extend over a column of access transistors 310 within the two-dimensional array of access transistors 310 (which comprises a set of N access transistors 310), and are electrically connected to each source region 332 within the set of N access transistors 310. N is an integer greater than 1.

In one embodiment, the plurality of interconnection via structures 66 within each vertical connection structure 660 comprises two first interconnection via structures (such as two first-via-level connection via structures 661) each contacting a top surface of a respective one of the two first source lines 64S and laterally spaced from each other along a second horizontal direction hd2 that is perpendicular to the first horizontal direction hd1. In one embodiment, the at least one line-level metal structure 68 within each vertical connection structure 660 comprises a first metal pad (comprising a second-line-level metal structure 682) contacting top surfaces of the two first interconnection via structures (such as two first-via-level connection via structures 661). In one embodiment, the plurality of interconnection via structures 66 of each vertical connection structure 660 comprises a second interconnection via structure (such as a second-via-level connection via structure 662) contacting a top surface of the first metal pad (comprising a second-line-level metal structure 682). In this embodiment, the second interconnection via structure (such as a second-via-level connection via structure 662) may be the only metallic structure that the top surface of the first metal pad (comprising a second-line-level metal structure 682) contacts.

In one embodiment, the plurality of interconnection via structures 66 within the vertical connection structure 660 comprises at least three additional interconnection via structures 66 that are vertically spaced from one another and having an areal overlap thereamongst in the plan view. For example, the plurality of interconnection via structures 66 within the vertical connection structure 660 may comprise a third-via-level connection via structure 663, a fourth-via-level connection via structure 664, a fifth-via-level connection via structure 665, a sixth-via-level connection via structure 666, a seventh-via-level connection via structure 667, and/or an eighth-via-level connection via structure 668. Each of the at least three additional interconnection via structures 66 overlies the two first interconnection via structures (such as two first-via-level connection via structures 661).

For each column of resistive memory structures 360 that is electrically connected to a column of access transistors 310, a bit line 64B is provided, which overlies a horizontal plane including top surfaces of the column of resistive memory structures 360 and is electrically connected to top electrodes of the column of resistive memory structures 360 within the two-dimensional array of resistive memory structures 360. In one embodiment, a second source line 69S overlies the bit line 64B, and may have an areal overlap with the bit line 64B in the top-down view. In one embodiment, the second source line 69S has an areal overlap with each of the two first source lines 64S in the plan view.

Generally, a column of access transistors 310 may be located on a semiconductor substrate 10, and may be arranged along the first horizontal direction hd1. Metal interconnect structures (62, 64, 66, 68) may be provided, which are embedded in dielectric material layers (50, 70), and are electrical connected to electrical nodes of the access transistors 310. A column of resistive memory structures 360 may be embedded in the dielectric material layers such as the upper-level dielectric material layers 70. For each combination of a column of access transistors 310 and a column of resistive memory structures 360, the metal interconnect structures (62, 64, 66, 68) may comprise two first source lines 64S located at a first metal line level that is vertically spaced from a top surface of the semiconductor substrate 10 by a first vertical spacing and laterally extending along a first horizontal direction hd1; first source contact via structures 62S contacting a bottom source of one of the two first source lines 64S; and second source contact via structures 62S contacting a bottom surface of another of the two first source lines 64S. Each source region 332 within the column of access transistors 310 is contacted by a respective one of the first source contact via structures 62S and by a respective one of the second source contact via structures 62S.

For each combination of a column of access transistors 310 and a column of resistive memory structures 360, the metal interconnect structures (62, 64, 66, 68) may comprise a second source line 69S located at a second metal line level that is vertically spaced from the top surface of the semiconductor substrate 10 by a second vertical spacing that is different from the first vertical spacing and laterally extending along the first horizontal direction hd1; and a vertical connection structure 660 comprising a plurality of interconnection via structures 66 and at least one line-level metal structure 68 and providing a vertical electrical connection between the two first source lines 64S and the second source line 69S.

For each combination of a column of access transistors 310 and a column of resistive memory structures 360, a bit line 64B may be provided, which overlies a horizontal plane including top surfaces of the column of resistive memory structures 360 and is electrically connected to top electrodes within the column of resistive memory structures 360. The second source line 69S may overlies the bit line 64B.

Referring to FIGS. 3A-3E, a second configuration of the exemplary structure according to an embodiment of the present disclosure is illustrated. The second configuration of the exemplary structure may be derived from the first configuration of the exemplary structure by forming additional source lines 65S at the third-metal-line level. In this embodiment, the pattern of the metal lines at the third-metal-line level (as shown in FIG. 3E) may be the same as the pattern of metal lines at the first-metal-line level (as shown in FIG. 3D).

The second source line 69S may be formed above the bit lines 64B, and the additional source lines 65S formed at the third-metal-line level may be referred to as third source lines. Alternatively, additional source lines 65S formed at the third-metal-line level may be referred to as second source lines. As discussed above, ordinals are not a part of a name of an element, and the various source lines (64S, 69S, 65S) may be referred to with different ordinals.

For each combination of a column of access transistors 310 and a column of resistive memory structures 360, the metal interconnect structures (62, 64, 66, 68) may comprise two first source lines 64S located at a first metal line level that is vertically spaced from a top surface of the semiconductor substrate 10 by a first vertical spacing and laterally extending along a first horizontal direction hd1; first source contact via structures 62S contacting a bottom source of one of the two first source lines 64S; and second source contact via structures 62S contacting a bottom surface of another of the two first source lines 64S. Each source region 332 within the column of access transistors 310 is contacted by a respective one of the first source contact via structures 62S and by a respective one of the second source contact via structures 62S.

For each combination of a column of access transistors 310 and a column of resistive memory structures 360, the metal interconnect structures (62, 64, 66, 68) may comprise a second source line 69S located at a second metal line level that is vertically spaced from the top surface of the semiconductor substrate 10 by a second vertical spacing that is different from the first vertical spacing and laterally extending along the first horizontal direction hd1; and a vertical connection structure 660 comprising a plurality of interconnection via structures 66 and at least one line-level metal structure 68 and providing a vertical electrical connection between the two first source lines 64S and the second source line 69S. The second source line 69S may overlie a bit line 64B that is connected to second electrodes 366 of the resistive memory structures 360.

For each combination of a column of access transistors 310 and a column of resistive memory structures 360, the metal interconnect structures (62, 64, 66, 68) comprise two additional source lines 65S (which may be referred to as two second source lines or as two third source lines) located at an additional metal line level (which may be referred to as a second metal line level or as a third metal line level) that is vertically spaced from the top surface of the semiconductor substrate 10 by a vertical spacing that is different from the first vertical spacing and laterally extending along the first horizontal direction hd1. The two additional source lines 65S may be formed at the third-metal-line level. A first vertical connection structure 660 may provide a first electrical connection between one of the two first source lines 64S and one of the two additional source lines 65S, and a second vertical interconnect structure providing a second electrical connection between another of two first source lines 64S and another of the two additional source lines 65S. In this configuration, source lines (64S, 69S, 65S) may be formed at three different metal line levels, and may be interconnected to one another by vertical connection structures 660.

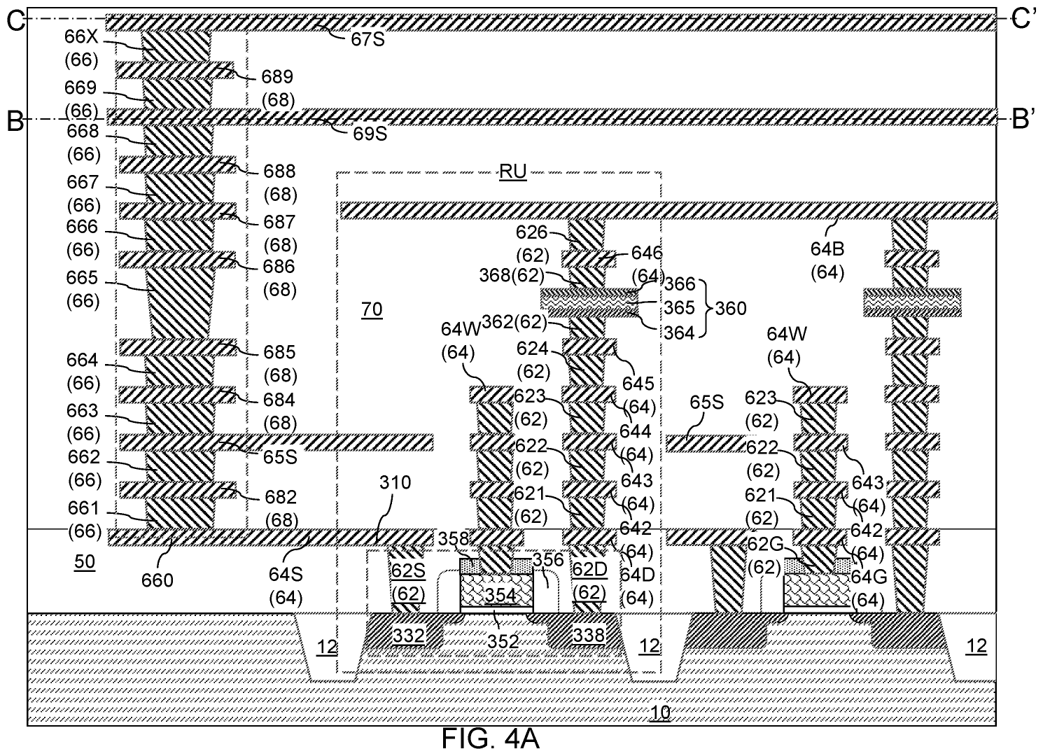

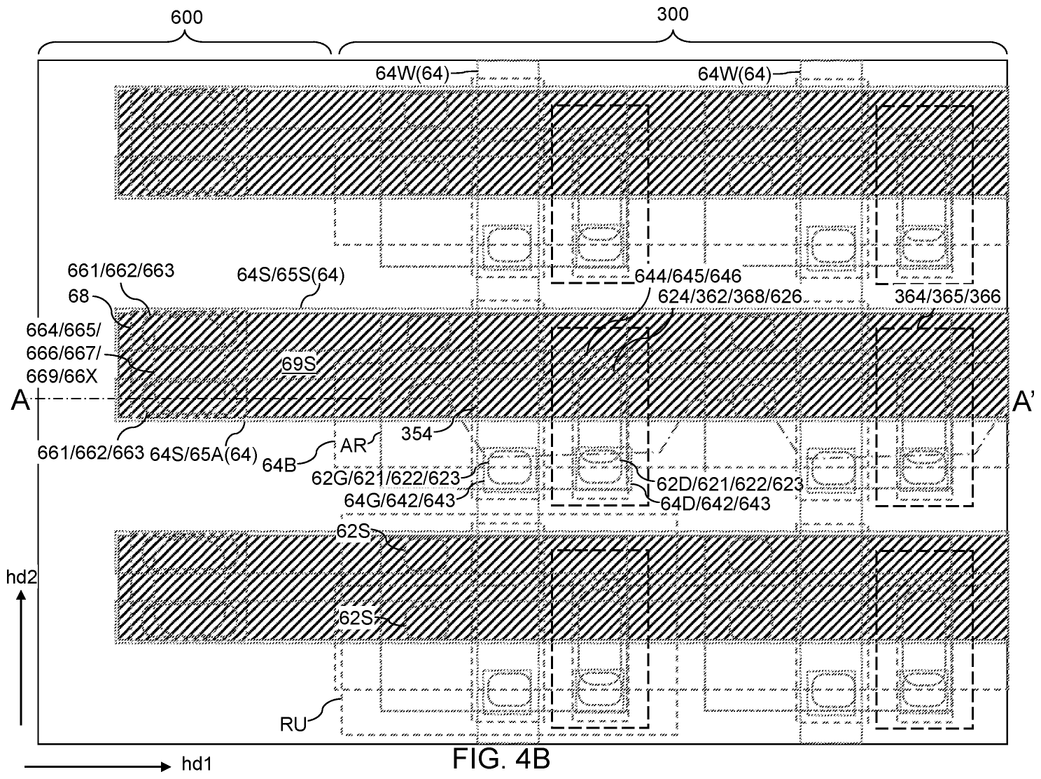

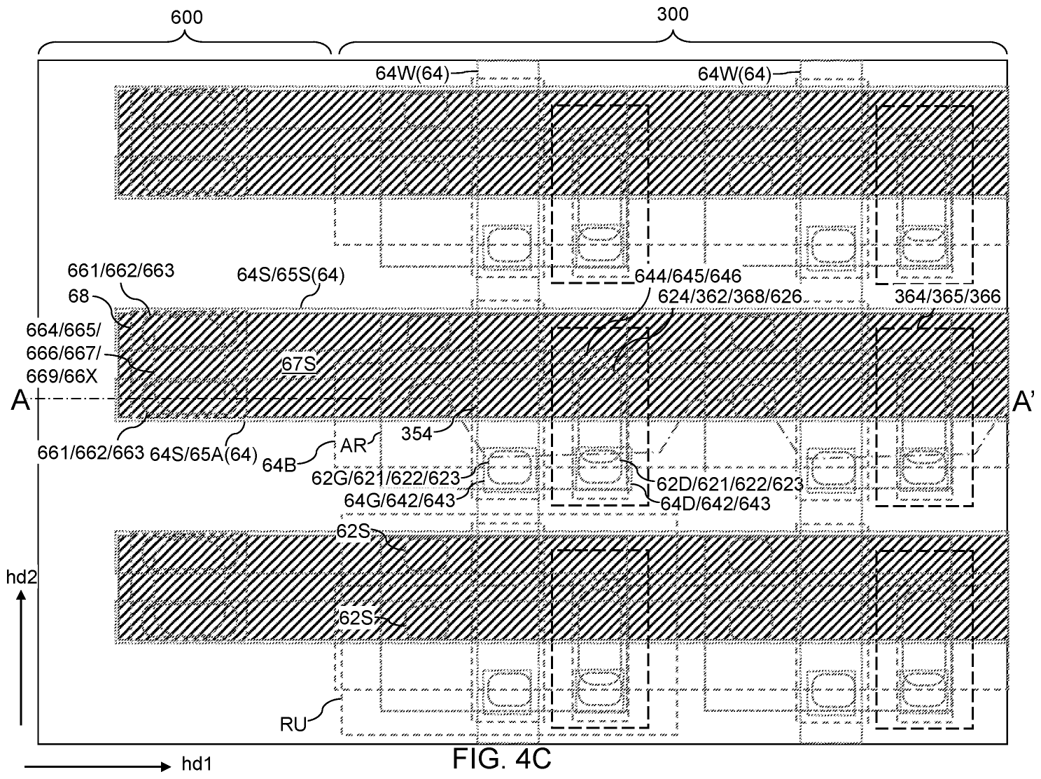

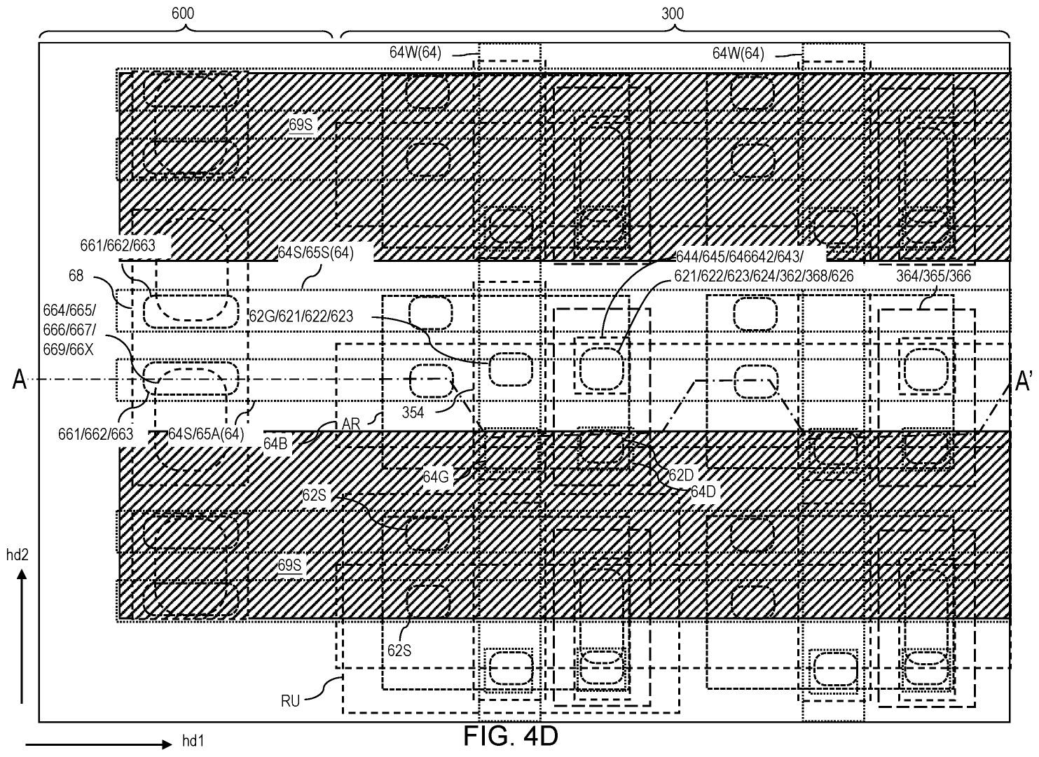

Referring to FIGS. 4A-4C, a third configuration of the exemplary structure may be derived from the second configuration of the exemplary structure by forming yet additional source lines 67S. In this configuration, the interconnection via structures 66 may further comprise ninth-via-level connection via structures 669 that are formed in a ninth-metal-via level, and tenth-via-level connection via structures 66X that are formed in a tenth-metal-via level. The line-level metal structures 68 may comprise ninth-line-level metal structures 689 that are formed in a ninth-metal-line level. The yet additional source lines 67S may be formed as a subset of tenth-line-level metal structures. The yet additional source lines 67S may be referred to as fourth source lines, third source lines, second source lines, or first source lines in this disclosure.

The third configuration of the exemplary structure may comprise each component within he second configuration of the exemplary structure described with reference to FIGS. 3A-3E. For each combination of a column of access transistors 310 and a column of resistive memory structures 360, the metal interconnect structures (62, 64, 66, 68) may comprise a yet additional source line 67S located at a respective metal line level that is vertically spaced from the top surface of the semiconductor substrate 10 by a vertical spacing that is different from the first vertical spacing and laterally extending along the first horizontal direction hd1; and a vertical connection structure 660 comprising a plurality of interconnection via structures 66 and at least one line-level metal structure 68 and providing a vertical electrical connection between the two first source lines 64S and the yet additional source line 67S. The yet additional source line 67S may overlie a bit line 64B that is connected to second electrodes 366 of the resistive memory structures 360.

Referring to FIG. 4D, an alternative embodiment of the third configuration of the exemplary structure may be derived from the third configuration of the exemplary structure by modifying the layout of the second source lines 69S, line-level metal structures 68, and upper-level connection via structures such as the fourth-via-level connection via structures 664 and overlying connection via structures. In this embodiment, the width of each second source line 69S along the second horizontal direction hd2 may be greater than six times the width of each first source line 64S. A first subset of the first source lines 64S has a full areal overlap with a respective overlying second source line 69S, while a second subset of the first source lines 64S does not have an areal overlap with any overlying second source line 69S or has only a partial overlap with an overlying second source line 69S. Each first source line 64S within the first subset is electrically shorted to a respective overlying second source line 69S, which lowers the effective source resistance of the first source line 64S. Each first source line 64S within the second subset is not only electrically shorted to a neighboring first source line 64S, but is also electrically shorted to a pair of second source lines 69S through two sets of vertical electrical connection structures each including a respective stack of line-level metal structures 68 and upper-level connection via structures 66. The pair of second source lines 69S can dramatically lower the source resistance for each source line 64S within the second subset.

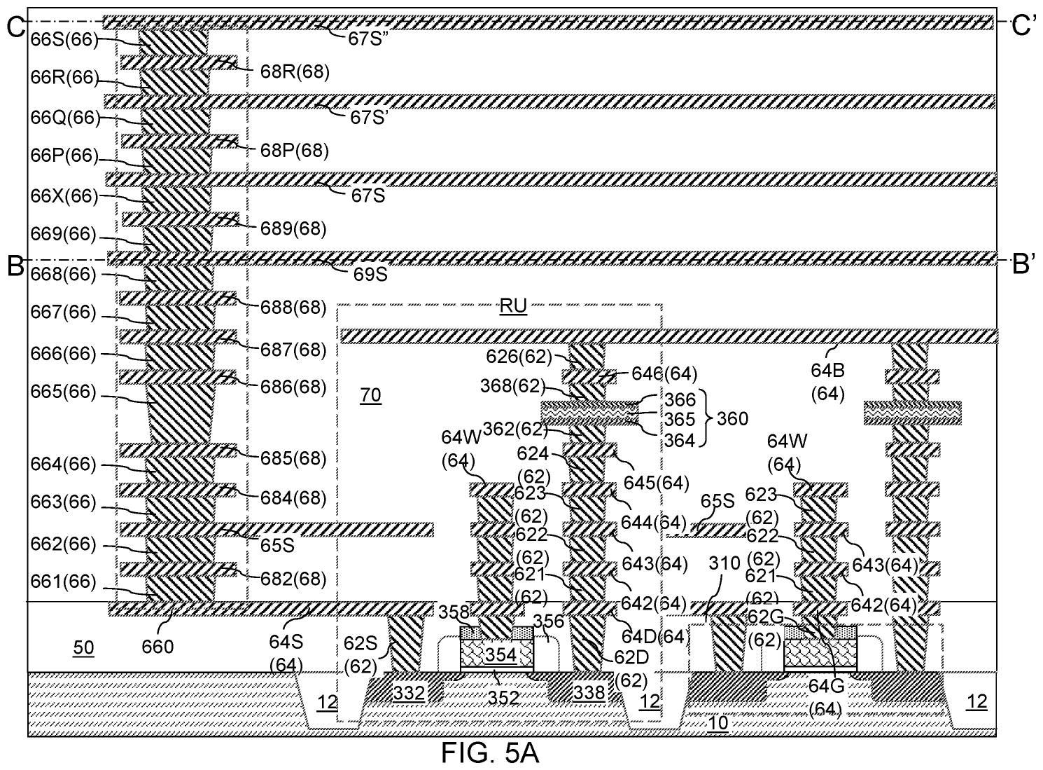

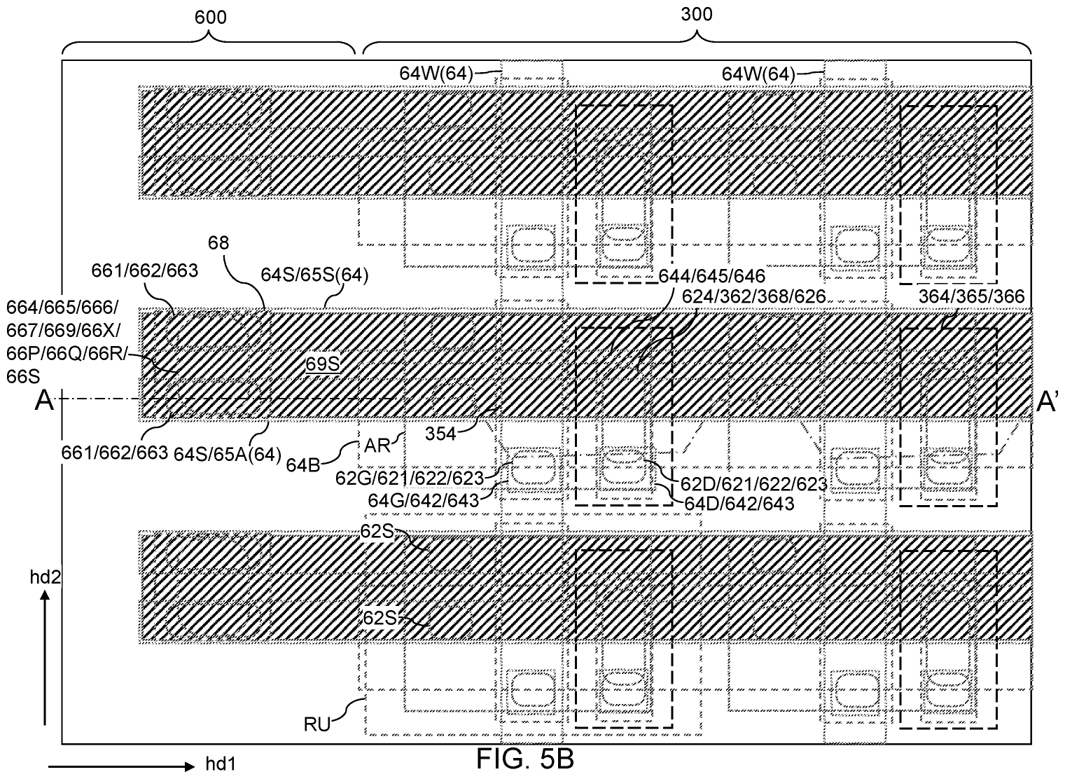

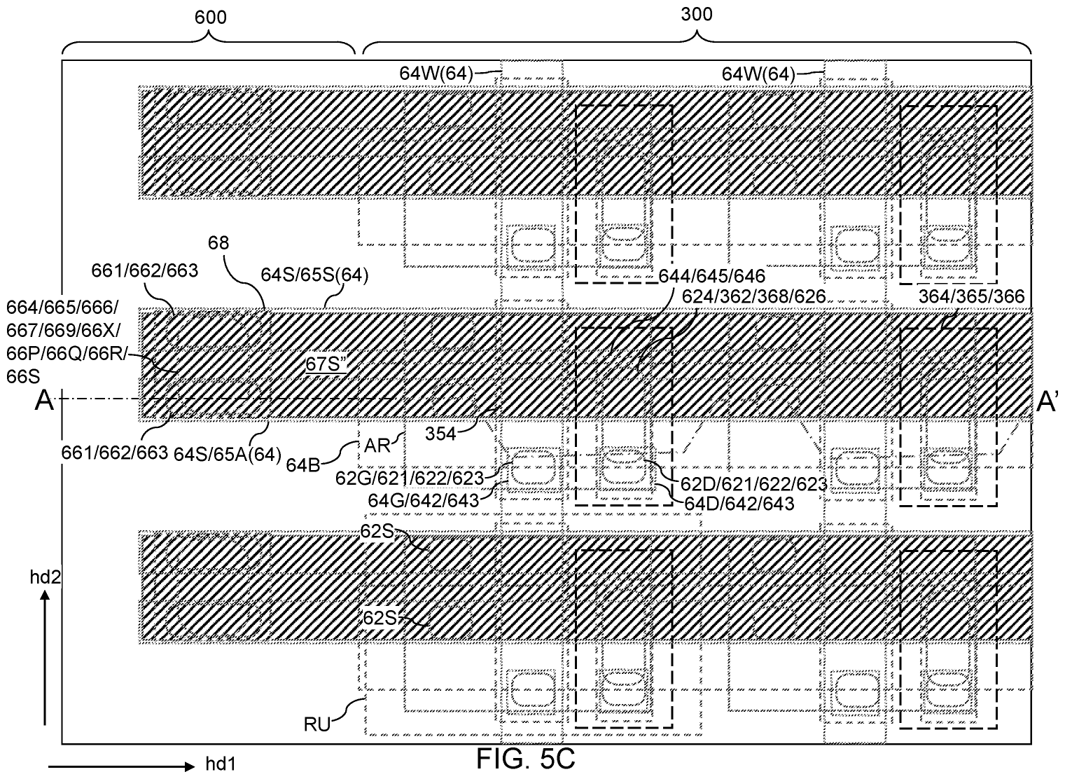

Referring to FIGS. 5A-5C, a fourth configuration of the exemplary structure may be derived from the third configuration of the exemplary structure by forming further additional source lines (67S′, 67S″). In this configuration, the interconnection via structures 66 may further comprise eleventh-via-level connection via structures 66P that are formed in an eleventh-metal-via level, twelfth-via-level connection via structures 66Q that are formed in a eleventh-metal-via level, thirteenth-via-level connection via structures 66R that are formed in a thirteenth-metal-via level, and fourteenth-via-level connection via structures 66S that are formed in a fourteenth-metal-via level. The line-level metal structures 68 may comprise eleventh-line-level metal structures 68P that are formed in an eleventh-metal-line level, and thirteenth-line-level metal structures 68R that are formed in a thirteenth-metal-line level. The further additional source lines (67S′, 67S″) may be formed as a subset of twelfth-line-level metal structures and fourteenth-line-level metal line structures. The further additional source lines (67S′, 67S″) may be referred to as sixth source lines, fifth source lines, fourth source lines, third source lines, second source lines, or first source lines in the this disclosure.

The fourth configuration of the exemplary structure may comprise each component within the second configuration of the exemplary structure described with reference to FIGS. 4A-4C. For each combination of a column of access transistors 310 and a column of resistive memory structures 360, the metal interconnect structures (62, 64, 66, 68) may comprise at least one further additional source line (67S′, 67S″) located at a respective metal line level that is vertically spaced from the top surface of the semiconductor substrate 10 by a vertical spacing that is different from the first vertical spacing and laterally extending along the first horizontal direction hd1; and a vertical connection structure 660 comprising a plurality of interconnection via structures 66 and at least one line-level metal structure 68 and providing a vertical electrical connection between the two first source lines 64S and the at least one further additional source line (67S′, 67S″). Each further additional source line 67S may overlie a bit line 64B that is connected to second electrodes 366 of the resistive memory structures 360.

Referring collectively to FIGS. 1A-5C and according to various embodiments of the present disclosure, a memory device is provided, which comprises: a two-dimensional array of access transistors 310 located on a semiconductor substrate 10; metal interconnect structures (62, 64, 66, 68) formed within dielectric material layers 70 and electrical connected to electrical nodes of each of the two-dimensional array of access transistors 310; and a two-dimensional array of resistive memory structures 360 formed within the dielectric material layers 70. The metal interconnect structures (62, 64, 66, 68) comprise: two first source lines 64S located at a first metal line level that is vertically spaced from a top surface of the semiconductor substrate 10 by a first vertical spacing and laterally extending along a first horizontal direction hd1; a second source line (69S, 65S, 67S, 67S′, 67S″) located at a second metal line level that is vertically spaced from the top surface of the semiconductor substrate 10 by a second vertical spacing that is different from the first vertical spacing and laterally extending along the first horizontal direction hd1; and a vertical connection structure 660 comprising a plurality of interconnection via structures 66 and at least one line-level metal structure 68 and providing a vertical electrical connection between the two first source lines 64S and the second source line (69S, 65S, 67S, 67S′, 67S″).

In one embodiment, the vertical connection structure 660 continuously extends from top surfaces of the two first source lines 64S to a bottom surface of the second source line (69S, 65S, 67S, 67S′, 67S″). In one embodiment, the two-dimensional array of resistive memory structures 360 is located within a memory array region in a plan view; and the vertical connection structure 660 is located within a vertical connection region that is laterally offset from the memory array region in the plan view.

In one embodiment, the two first source lines 64S laterally extend over a column of access transistors 310 within the two-dimensional array of access transistors 310 that comprises a set of N access transistors 310, and are electrically connected to each source region 332 within the set of N access transistors 310, N being an integer greater than 1. In one embodiment, the memory device comprises two columns of source contact via structures 62S arranged along the first horizontal direction hd1, wherein each source contact via structure 62S contacts a bottom surface of a respective one of the two first source lines 64S and contacts a top surface of a source region 332 of a respective access transistor 310 within the column of access transistors 310. In one embodiment, each source region 332 within the column of access transistors 310 is contacted by a respective first source contact via structure 62S that contacts a bottom surface of one of the two first source lines 64S and by a respective second source contact via structure 62S that contacts a bottom surface of another of the two first source lines 64S.

In one embodiment, the plurality of interconnection via structures 66 of the vertical connection structure 660 comprises two first interconnection via structures (such as two first-via-level connection via structures 661) each contacting a top surface of a respective one of the two first source lines 64S and laterally spaced from each other along a second horizontal direction hd2 that is perpendicular to the first horizontal direction hd1.

In one embodiment, the at least one line-level metal structure 68 comprises a first metal pad (comprising a second-line-level metal structure 682) contacting top surfaces of the two first interconnection via structures (such as two first-via-level connection via structures 661); and the plurality of interconnection via structures 66 of the vertical connection structure 660 comprises a second interconnection via structure (such as a second-via-level connection via structure 662) contacting a top surface of the first metal pad (comprising a second-line-level metal structure 682), the second interconnection via structure (such as a second-via-level connection via structure 662) being the only metallic structure that the top surface of the first metal pad (comprising a second-line-level metal structure 682) contacts.

In one embodiment, the plurality of interconnection via structures 66 of the vertical connection structure 660 comprises at least three additional interconnection via structures 66 that are vertically spaced from one another and having an areal overlap thereamongst in the plan view. Each of the at least three additional interconnection via structures 66 overlies the two first interconnection via structures (such as two first-via-level connection via structures 661).

In one embodiment, the memory device comprises a bit line 64B that overlies a horizontal plane including top surfaces of the resistive memory structures 360 and electrically connected to top electrodes of a column of resistive memory structures 360 within the two-dimensional array of resistive memory structures 360. The second source line (69S, 65S, 67S, 67S′, 67S″) overlies the bit line 64B. In one embodiment, the second source line (69S, 65S, 67S, 67S′, 67S″) has an areal overlap with each of the two first source lines 64S in the plan view.

According to another aspect of the present disclosure, a memory device is provided, which comprises: a column of access transistors 310 located on a semiconductor substrate 10 and arranged along a first horizontal direction hd1; metal interconnect structures (62, 64, 66, 68) formed within dielectric material layers 70 and electrical connected to electrical nodes of each of the column of access transistors 310; and a column of resistive memory structures 360 formed within the dielectric material layers 70. The metal interconnect structures (62, 64, 66, 68) comprise: two first source lines 64S located at a first metal line level that is vertically spaced from a top surface of the semiconductor substrate 10 by a first vertical spacing and laterally extending along a first horizontal direction hd1; first source contact via structures 62S contacting a bottom source of one of the two first source lines 64S; and second source contact via structures 62S contacting a bottom surface of another of the two first source lines 64S, wherein each source region 332 within the column of access transistors 310 is contacted by a respective one of the first source contact via structures 62S and by a respective one of the second source contact via structures 62S.

In one embodiment, the metal interconnect structures (62, 64, 66, 68) comprise: a second source line (69S, 65S, 67S, 67S′, 67S″) located at a second metal line level that is vertically spaced from the top surface of the semiconductor substrate 10 by a second vertical spacing that is different from the first vertical spacing and laterally extending along the first horizontal direction hd1; and a vertical connection structure 660 comprising a plurality of interconnection via structures 66 and at least one line-level metal structure 68 and providing a vertical electrical connection between the two first source lines 64S and the second source line (69S, 65S, 67S, 67S′, 67S″).

In one embodiment, the memory device comprises a bit line 64B that overlies a horizontal plane including top surfaces of the column of resistive memory structures 360 and electrically connected to top electrodes within the column of resistive memory structures 360, wherein the second source line (69S, 65S, 67S, 67S′, 67S″) overlies the bit line 64B.

In one embodiment, the metal interconnect structures (62, 64, 66, 68) comprise: two second source lines (69S, 65S, 67S, 67S′, 67S″) located at a second metal line level that is vertically spaced from the top surface of the semiconductor substrate 10 by a second vertical spacing that is different from the first vertical spacing and laterally extending along the first horizontal direction hd1; a first vertical connection structure 660 providing a first electrical connection between one of the two first source lines 64S and one of the two second source lines (69S, 65S, 67S, 67S′, 67S″); and a second vertical connection structure 660 providing a second electrical connection between another of two first source lines 64S and another of the two second source lines (69S, 65S, 67S, 67S′, 67S″).

According to an embodiment of the present disclosure, each of the first source lines 64S and the at least one second source line (69S, 65S, 67S, 67S′, 67S″) may laterally extend along a same horizontal direction (such as the first horizontal direction hd1), and may be formed at a respective odd-numbered line level. For example, the first source lines 64S may be formed at the first line level, and each of the at least one second source line (69S, 65S, 67S, 67S′, 67S″) may be formed at a respective odd-numbered line level such as a third line level, a fifth line level, a seventh line level, a ninth line level, etc. There may be at least one odd-numbered level that does not include any source line.

According to an embodiment of the present disclosure, the source lines (64S, 69S, 65S, 67S, 67S′, 67S″) and the bit lines 64B can laterally extend along a same horizontal direction (such as the first horizontal direction hd1). Each of the source lines (64S, 69S, 65S, 67S, 67S′, 67S″) and the bit lines 64B may be formed at a respective odd-numbered line level. Word lines 64W laterally extend along a horizontal direction (such as the second horizontal direction h2) that is different from the lateral extension direction of the source lines (64S, 69S, 65S, 67S, 67S′, 67S″) and the bit lines 64B. In one embodiment, the word lines 64W can be located at an even-numbered line level, which may be a second line level, a fourth line level, a sixth line level, etc. In one embodiment, the lateral extension direction of the word lines 64W (such as the second horizonal direction hd2) can be perpendicular to the lateral extension direction of the source lines (64S, 69S, 65S, 67S, 67S′, 67S″) and the bit lines 64B (such as the first horizontal direction hd1).

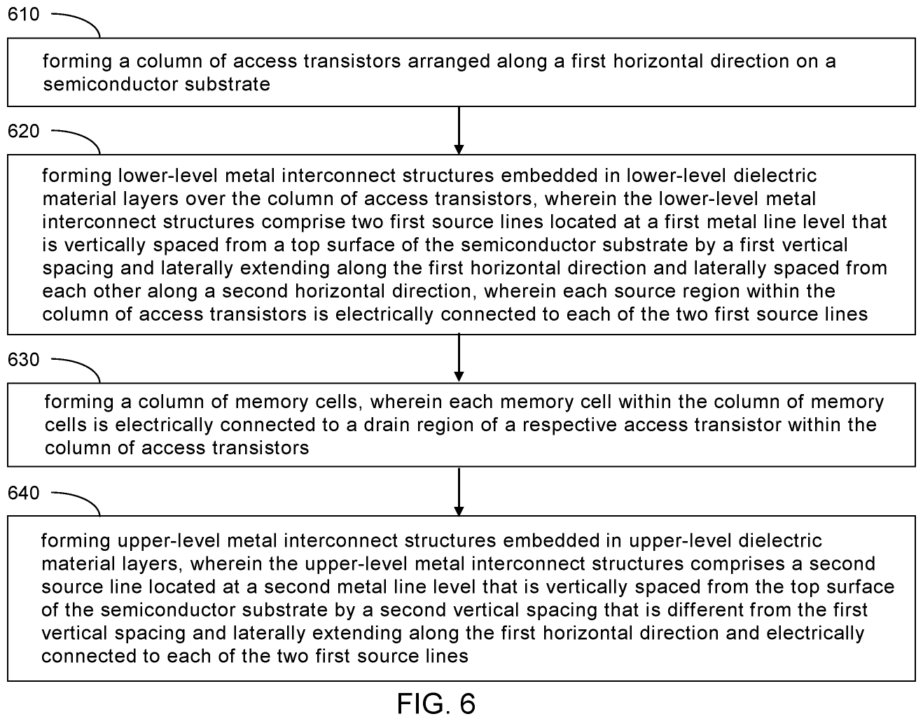

FIG. 6 is a flowchart illustrating steps for forming a memory device according to an embodiment of the present disclosure.

Referring to step 610 and FIGS. 1A-1C, a column of access transistors 310 may be formed, which may be arranged along a first horizontal direction hd1 on a semiconductor substrate 10.

Referring to step 620 and FIGS. 1A-1C, lower-level metal interconnect structures (62, 64) embedded in lower-level dielectric material layers 50 may be formed over the column of access transistors 310. The lower-level metal interconnect structures (62, 64) comprise two first source lines 64S located at a first metal line level that is vertically spaced from a top surface of the semiconductor substrate 10 by a first vertical spacing and laterally extending along the first horizontal direction hd1 and laterally spaced from each other along a second horizontal direction hd2. Each source region 332 within the column of access transistors 310 is electrically connected to each of the two first source lines 64S.

Referring to step 630 and FIGS. 2A-5C, a column of resistive memory structures 360 may be formed. Each resistive memory structure 360 within the column of resistive memory structures 360 is electrically connected to a drain region of a respective access transistor 310 within the column of access transistors 310.

Referring to step 640 and FIGS. 2A-5C, upper-level metal interconnect structures (62, 64, 66, 68) formed within upper-level dielectric material layers 70 may be formed. The upper-level metal interconnect structures (62, 64, 66, 68) comprise a second source line (69S, 65S, 67S, 67S′, 67S″) located at a second metal line level that is vertically spaced from the top surface of the semiconductor substrate 10 by a second vertical spacing that is different from the first vertical spacing and laterally extending along the first horizontal direction hd1 and electrically connected to each of the two first source lines 64S.

The various embodiments of the present disclosure may be used to provide a memory array including source lines (64S, 69S, 65S, 67S, 67S′, 67S″) provided at more than two metal line levels. The duplicate or multiplicate levels of the source lines (64S, 69S, 65S, 67S, 67S′, 67S″) may provide low resistance source-side electrically conductive paths that lower source line resistance and provide stable threshold voltage for the access transistors 310, and thus, enhances device stability of the memory array.

As discussed above, the present disclosure provides reduction in the source resistance in a RRAM array. By reducing the source resistance, the various embodiments disclosed herein may provide a RRAM array having a more stable and predictable operational characteristics, enhanced reliability, increased energy efficiency, and superior overall performance. Such enhancements in a RRAM array allows memory storage solutions with higher speed and reliability, of which the demand continues to grow, driven by advancements in computing technologies and the increasing data storage needs of various applications.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph of in different paragraphs, a Markush group including a listing of the two or more elements may be also impliedly disclosed in some embodiments. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device comprising:
an array of access transistors located on a semiconductor substrate;
metal interconnect structures formed within dielectric material layers and electrically connected to electrical nodes of each of the array of access transistors; and
an array of resistive memory structures located within the dielectric material layers and electrically connected to a respective one of the access transistors,
wherein the metal interconnect structures comprise:
at least one first source line located at a first metal line level that is vertically spaced from a top surface of the semiconductor substrate by a first vertical spacing and laterally extending along a first horizontal direction;
a second source line located at a second metal line level that is vertically spaced from the top surface of the semiconductor substrate by a second vertical spacing that is different from the first vertical spacing and laterally extending along the first horizontal direction; and
a vertical connection structure comprising a plurality of interconnection via structures and at least one line-level metal structure and providing a vertical electrical connection between the at least one first source line and the second source line.

2. The memory device of claim 1, wherein:
the at least one first source line comprises two first source lines; and
the vertical connection structure continuously extends from top surfaces of the two first source lines to a bottom surface of the second source line.

3. The memory device of claim 2, wherein:
the array of resistive memory structures is located within a memory array region in a plan view; and
the vertical connection structure is located within a vertical connection region that is laterally offset from the memory array region in the plan view.

4. The memory device of claim 1, wherein the two first source lines laterally extend over a column of access transistors within the array of access transistors that comprises a set of N access transistors, and are electrically connected to each source region within the set of N access transistors, N being an integer greater than 1.

5. The memory device of claim 4, further comprising two columns of source contact via structures arranged along the first horizontal direction, wherein each source contact via structure contacts a bottom surface of a respective one of the two first source lines and contacts a top surface of a source region of a respective access transistor within the column of access transistors.

6. The memory device of claim 4, wherein each source region within the column of access transistors is contacted by a respective first source contact via structure that contacts a bottom surface of one of the two first source lines and by a respective second source contact via structure that contacts a bottom surface of another of the two first source lines.

7. The memory device of claim 1, wherein the plurality of interconnection via structures of the vertical connection structure comprises two first interconnection via structures each contacting a top surface of a respective one of the two first source lines and laterally spaced from each other along a second horizontal direction that is perpendicular to the first horizontal direction.

8. The memory device of claim 7, wherein:
the at least one line-level metal structure comprises a first metal pad contacting top surfaces of the two first interconnection via structures; and
the plurality of interconnection via structures of the vertical connection structure comprises a second interconnection via structure contacting a top surface of the first metal pad, the second interconnection via structure being the only metallic structure that the top surface of the first metal pad contacts.

9. The memory device of claim 7, wherein the plurality of interconnection via structures of the vertical connection structure comprises at least three additional interconnection via structures that are vertically spaced among one another and having an areal overlap thereamongst in a plan view, wherein each of the at least three additional interconnection via structures overlies the two first interconnection via structures.

10. The memory device of claim 1, further comprising a bit line that overlies a horizontal plane including top surfaces of each of the array of resistive memory structures and electrically connected to top electrodes of a column of resistive memory structures within the array of resistive memory structures, wherein the second source line overlies the bit line.

11. The memory device of claim 1, wherein the second source line has an areal overlap with each of the two first source lines in a plan view.

12. A memory device comprising:
a column of access transistors located on a semiconductor substrate and arranged along a first horizontal direction;
metal interconnect structures embedded in dielectric material layers and electrical connected to electrical nodes of each of the column of access transistors; and
a column of resistive memory structures formed within the dielectric material layers,
wherein the metal interconnect structures comprise:
two first source lines located at a first metal line level that is vertically spaced from a top surface of the semiconductor substrate by a first vertical spacing and laterally extending along a first horizontal direction;
first source contact via structures located on a bottom source of one of the two first source lines; and
second source contact via structures located on a bottom surface of another of the two first source lines, wherein each source region within the column of access transistors is located on a respective one of the first source contact via structures and on a respective one of the second source contact via structures.

13. The memory device of claim 12, wherein the metal interconnect structures comprise:
a second source line located at a second metal line level that is vertically spaced from the top surface of the semiconductor substrate by a second vertical spacing that is different from the first vertical spacing and laterally extending along the first horizontal direction; and
a vertical connection structure comprising a plurality of interconnection via structures and at least one line-level metal structure and providing a vertical electrical connection between the two first source lines and the second source line.

14. The memory device of claim 12, further comprising a bit line that overlies a horizontal plane including top surfaces of the column of resistive memory structures and electrically connected to top electrodes within the column of resistive memory structures, wherein the second source line overlies the bit line.

15. The memory device of claim 12, wherein the metal interconnect structures comprise:
two second source lines located at a second metal line level that is vertically spaced from the top surface of the semiconductor substrate by a second vertical spacing that is different from the first vertical spacing and laterally extending along the first horizontal direction;
a first vertical connection structure providing a first electrical connection between one of the two first source lines and one of the two second source lines; and
a second vertical connection structure providing a second electrical connection between another of two first source lines and another of the two second source lines.

16. A method of forming a memory device, the method comprising:
forming a column of access transistors arranged along a first horizontal direction on a semiconductor substrate;
forming lower-level metal interconnect structures formed within lower-level dielectric material layers over the column of access transistors, wherein the lower-level metal interconnect structures comprise two first source lines located at a first metal line level that is vertically spaced from a top surface of the semiconductor substrate by a first vertical spacing and laterally extending along the first horizontal direction and laterally spaced from each other along a second horizontal direction, wherein each source region within the column of access transistors is electrically connected to each of the two first source lines;
forming a column of resistive memory structures, wherein each resistive memory structure within the column of resistive memory structures is electrically connected to a drain region of a respective access transistor within the column of access transistors; and
forming upper-level metal interconnect structures formed within upper-level dielectric material layers, wherein the upper-level metal interconnect structures comprise a second source line located at a second metal line level that is vertically spaced from the top surface of the semiconductor substrate by a second vertical spacing that is different from the first vertical spacing and laterally extending along the first horizontal direction and electrically connected to each of the two first source lines.

17. The method of claim 16, further comprising forming a vertical connection structure vertically connecting the two first source lines and the second source line, wherein the vertical connection structure comprises a plurality of interconnection via structures and at least one line-level metal structure.

18. The method of claim 16, wherein:
the column of access transistors is formed within a memory array region; and
a vertical connection structure is formed within a vertical connection region that is laterally offset from the memory array region in a plan view.

19. The method of claim 16, wherein:
the lower-level metal interconnect structures comprise a column of first source contact via structures and a column of second source contact via structures;
one of the two first source lines is formed on the column of first source contact via structures;
another of the two first source lines is formed on the column of second source contact via structures; and
each source region within the column of access transistors is contacted by a respective one of the first source contact via structures and by a respective one of the second source contact via structures.

20. The method of claim 16, wherein:
the upper-level metal interconnect structures comprises a bit line that overlies a horizontal plane including top surfaces of the column of resistive memory structures and electrically connected to top electrodes of the column of resistive memory structures; and
the second source line is formed over the bit line.
